(19) United States
(12) Patent Application Publication
(10) Pub. No.: US 2023/0360922 A1
(43) Pub. Date: Nov. 9, 2023

(54) ROBUST ASHABLE HARD MASK

(71) Applicant: Lam Research Corporation, Fremont, CA (US)

(72) Inventors: Matthew Scott WEIMER, Portland, OR (US); Ragesh PUTHENKOVILAKAM, Portland, OR (US); Kapu Sirish REDDY, Portland, OR (US)

(21) Appl. No.: 18/245,950

(22) PCT Filed: Sep. 23, 2021
(86) PCT No.: PCT/US2021/051776

§ 371 Date: Mar. 20, 2023

Related U.S. Application Data
(60) Provisional application No. 63/198,061, filed on Sep. 25, 2020.

(51) Int. Cl. H01L 21/308; H01L 21/311; H01L 21/02; H01J 37/32; C23C 16/04; C23C 16/509; C23C 16/56; C23C 16/44; C23C 16/26; C23C 16/458

(52) U.S. Cl. CPC H01L 21/3086; H01L 21/31105; H01L 21/02274; H01J 37/32926; C23C 16/042; C23C 16/509; C23C 16/56; C23C 16/4409; C23C 16/26; C23C 16/4585; H01J 2237/3321

(57) ABSTRACT

Provided herein are methods and related apparatuses for forming an ashable hard mask (AHM). In particular instances, use of a halogen-containing precursor can provide an AHM having improved etch resistance.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes. This application claims the benefit of U.S. Provisional Patent Application No. 63/198,061, filed Sep. 25, 2020, which is incorporated herein by reference in its entirety.

### FIELD

The present disclosure relates to methods and related apparatuses for forming an ashable hard mask (AHM). In particular instances, use of a halogen-containing precursor can provide an AHM having improved etch resistance.

### BACKGROUND

Amorphous carbon films may be used as hard masks and etch stop layers in semiconductor processing, including in memory and logic device fabrication. These films are also known as ashable hard masks (AHMs) because they may be removed by an ashing technique. As aspect ratios in lithography increase, AHMs require higher etch selectivity and/or greater thickness.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

The present disclosure relates to use of particular precursors to provide AHMs. In some embodiments, the AHM has improved etch resistance.

Accordingly, in a first aspect, the present disclosure encompasses a method including: exposing a surface of a semiconductor substrate in a processing chamber to a halogen-containing precursor, wherein the halogen-containing precursor is delivered to the processing chamber or formed in situ within the processing chamber; and depositing on the surface an ashable hard mask film (AHM) by a plasma enhanced chemical vapor deposition (PECVD) process.

In some embodiments, said exposing includes delivering the halogen-containing precursor to the processing chamber. In other embodiments, said exposing further includes delivering a process gas including the halogen-containing precursor and an inert gas. In yet other embodiments, said exposing further includes delivering a process gas including the halogen-containing precursor and an inert gas.

In some embodiments, the halogen-containing precursor includes a straight-chain or branched-chain aliphatic moiety, an aromatic moiety, a cycloaliphatic moiety, or a multicycloaliphatic moiety, in which each moiety includes one or more halo substitutions. In other embodiments, the one or more halo substitutions is provided on an sp carbon, an sp² carbon, an spa carbon, a branched portion, or an unbranched portion. In yet other embodiments, the halogen-containing precursor includes a halocarbon, a haloaliphatic, a haloalkane, a haloalkene, a haloalkyne, a haloaromatic, or a halocarbocycle.

In some embodiments, said exposing includes forming the halogen-containing precursor in situ within the processing chamber with an organic reactant and a halogen-containing reactant. In particular embodiments, the organic reactant includes a pure hydrocarbon reactant, a halocarbon reactant, a hydrocarbon reactant having a leaving group, or a heterocycle reactant. Non-limiting pure hydrocarbon reactants include an alkane, an alkene, an alkyne, an aromatic, or a carbocycle, as well as any described herein. Non-limiting halocarbon reactants include an alkane, an alkene, an alkyne, an aromatic, or a carbocycle including one or more halo substitutions. Non-limiting hydrocarbon reactants having the leaving group include an alkane, an alkene, an alkyne, an aromatic, or a carbocycle including one or more leaving groups (e.g., a halosulfonyl group, a sulfonate group, a cyano group, a nitrous oxide group (N₂O), a nitrate group (—ONO₂), or others described herein), such as an alkyl sulfonyl halide, an aryl sulfonyl halide, an alkyl triflate, an aryl triflate, an alkyl mesylate, an aryl mesylate, a cyanoalkane, a cyanoaromatic, an alkyl nitrate, or an aryl nitrate. Non-limiting halogen-containing reactants include a halide, a halogen gas, a tetrahalosilane, a trihalosilane, a dihalosilane, a monohalosilane, or a Grignard reagent.

In some embodiments, said exposing further includes delivering a first process gas including the organic reactant with a first inert gas and a second process gas including the halogen-containing reactant with a second inert gas (e.g., thereby forming the halogen-containing precursor in situ within the processing chamber).

In some embodiments, said exposing further includes delivering a hydrogen (H₂) gas.

In other embodiments, said exposing further includes delivering a hydrocarbon precursor with the halogen-containing precursor. Non-limiting hydrocarbon precursors include an alkane, an alkene, an alkyne, an aromatic, or a carbocycle.

In some embodiments, said exposing further includes delivering a metal-containing reactant and said depositing provides a metal-doped AHM. Non-limiting metal-containing reactants include an organometallic reagent, a metal halide, or a metal hydride.

In some embodiments, said PECVD process includes igniting a plasma including a low frequency (LF) component and/or a high frequency (HF) component.

In other embodiments, the method further includes: patterning the AHM, thereby providing a patterned AHM; and etching the patterned AHM to define features of the AHM in the semiconductor substrate. In some embodiments, the method further includes: etching one or more layers in the semiconductor substrate underlying the patterned AHM; and removing the patterned AHM.

In a second aspect, the present disclosure encompasses an apparatus for forming an AHM, the apparatus including: a processing chamber; a substrate holder in the processing chamber; one or more gas inlets for flowing gases into the processing chamber; a plasma generator for generating plasmas within the processing chamber; and one or more controllers including machine-readable instructions for operating the substrate holder, the one or more gas inlets, and the plasma generator to deposit the AHM onto a semiconductor substrate.

In some embodiments, the instructions of the one or more controllers include instructions for: (a) causing operation of the one or more gas inlets to flow a halogen-containing precursor or an organic reactant with a halogen-containing reactant into the processing chamber, wherein the organic reactant and the halogen-containing reactant form the halogen-containing precursor, thereby exposing a surface of the semiconductor substrate held in the substrate holder to the halogen-containing precursor. In other embodiments, the instructions of the one or more controllers include instructions for: (b) causing operation of the plasma generator to generate a plasma to form the AHM on the surface.

In yet other embodiments, the instructions of the one or more controllers include instructions for: (c) prior to causing operation of the plasma generator, further causing operation of the one or more gas inlets to flow a hydrogen (H₂) gas into the processing chamber. In some embodiments, the instructions of the one or more controllers include instructions for: (c) prior to causing operation of the plasma generator, further causing operation of the one or more gas inlets to flow a metal-containing reactant into the processing chamber.

In other embodiments, the instructions of the one or more controllers include instructions for: (c) causing operation of the substrate holder at a temperature of at least about 50° C.

In some embodiments, the plasma generator is operated to provide a plasma including a low frequency (LF) component and/or a high frequency (HF) component. The LF component and the HF component can be provided in continuous wave and/or pulsing modes, as described herein.

In any embodiment herein, the halogen-containing precursor includes a straight-chain or branched-chain aliphatic moiety, an aromatic moiety, a cycloaliphatic moiety, or a multicycloaliphatic moiety, in which each moiety includes one or more halo substitutions. In some embodiments, the one or more halo substitutions is provided on an sp carbon, an sp² carbon, an spa carbon, a branched portion, or an unbranched portion.

In any embodiment herein, the halogen-containing precursor includes a halocarbon, a haloaliphatic, a haloalkane, a haloalkene, a haloalkyne, a haloaromatic, or a halocarbocycle.

In any embodiment herein, the halogen-containing precursor includes a ratio of carbon atoms to halogen atoms (a C:H ratio) of at least about 1:3 and/or a ratio of halogen atoms to hydrogen atoms (an X:H ratio) of at least about 1:20.

In any embodiment herein, the method provides a multilayer stack including the AHM.

In any embodiment herein, the AHM is formed by using a precursor or a reactant described herein, such as a halogen-containing precursor, a hydrocarbon precursor, an organic reactant, a halogen-containing reactant, a pure hydrocarbon reactant, a halocarbon reactant, a hydrocarbon reactant having a leaving group, an aliphatic moiety, an aromatic moiety, a carbocycle, a heterocycle, an elemental halogen, a hydrogen gas, a metal-containing reactant, or a combination of any of these. Additional details follow.

### BRIEF DESCRIPTION OF THE DRAWINGS

FIG. 1 is a process flow diagram showing relevant operations of methods of using an ashable hard mask (AHM) in etching operations according to various embodiments.

FIG. 2A-2C provides process flow diagrams showing relevant operations of methods of forming an AHM.

FIG. 3 shows a schematic illustration of a plasma enhanced chemical vapor deposition (PECVD) chamber suitable for practicing various embodiments.

FIG. 4 shows another schematic illustration of another PECVD chamber suitable for practicing various embodiments.

FIG. 5 shows a schematic illustration of a module cluster suitable for practicing various embodiments.

FIG. 6A-6C shows schematic illustrations of yet another PECVD chamber suitable for practicing various embodiments.

FIG. 7 shows a schematic illustration an inductively coupled plasma etching apparatus for practicing various embodiments.

FIG. 8 shows a schematic illustration of a module cluster suitable for practicing various embodiments.

### DETAILED DESCRIPTION

### Introduction and Context

In semiconductor processing, masking methods are used to pattern and etch substrates. As substrate aspect ratios increase, the demand for highly selective hard masks increases. Masks that have high etch selectivity and yet are easy to remove without damage to the substrate are important to processing substrates. Ashable hard masks (AHMs) can be used as masks in etch stop layers, during selective etching, for high aspect-ratio (HAR) etching, or where a photoresist may not be thick enough to mask the underlying layer. AHMs may also be used on glass substrates used for displays and other technologies.

AHM films have a chemical composition that allows them to be removed by a technique referred to as “ashing,” “plasma ashing,” or “dry stripping” once they have served their purpose. Carbon hard masks can be removed cleanly with a process that does not greatly impact the newly formed features. An example of such process is contact with an oxygen plasma.

One example of an AHM film is an amorphous carbon layer or film. An AHM film is generally composed of carbon and hydrogen with, optionally, a small amount of one or more dopants (e.g., nitrogen, fluorine, boron, and silicon). The bonding structure of an AHM can vary from sp² (graphite-like) or spa (diamond-like), or a combination of both, depending on the deposition conditions.

Current applications of ashable hard masks include as a protective hard mask on top of a stack (e.g., alternating silicon oxide and nitride layers (ONON) or alternating silicon oxide and polysilicon layers (OPOP)) for the high aspect ratio (HAR) etching. Due to increasing stack heights, the hard mask thickness continues to increase. Some current applications require about 1.6 to 2.2 μm of AHM.

For many applications, the available AHM technology is limited to films that are relatively low in density and/or high in hydrogen content. Having low density or high hydrogen content significantly increases the etch rate during feature etch.

Because the film thickness is large, the AHMs must have a relatively low internal stress, e.g., close to neutral, −40 to −100 MPa. This low level of stress correlates to a relatively low modulus, e.g., around 50 GPa. In this regime, it has been observed that a decrease in hydrogen content of about 50% in an AHM gives an improvement in pattern etch selectivity of about 22%. Many AHMs often have a hydrogen content between about 10-12%, as measured by Rutherford Back Scattering/Hydrogen Forward Scattering (RBS/HFS).

With the demands on the mask thickness dictating some properties of the film, deposition rate, stress and transparency, any degradation in these properties requires a significant improvement in etch selectivity. In other words, the process cannot sacrifice deposition rate just to decrease hydrogen content. In other words, it would be advantageous to decrease the hydrogen content of these AHM films, without decreasing deposition rate or degrading other film properties.

Disclosed herein are systems and methods to improve characteristics of a carbon film or a doped carbon film over a range of deposition temperatures. For context, AHMs are often deposited at 150° C. to 650° C. Through judicious combination of carbon and halogen-containing precursors in the plasma gas with inert gases during plasma enhanced deposition, etch properties are improved, and/or the effective amount of hydrogen in the film is decreased. In some embodiments, the plasma enhanced deposition process is a conductively coupled plasma (CCP) process employing a single frequency or dual-frequency plasma source.

Various embodiments employ gaseous precursor species containing halogen, carbon, and hydrogen atoms. In particular, the precursor species includes a halogen-containing precursor. Such a precursor can be delivered into the processing chamber (e.g., with a halocarbon) or, in alternate embodiments, be formed in situ within the processing chamber (e.g., with an organic reactant and a halogen-containing reactant). Some such processes provide an AHM with a decrease in halogen and/or hydrogen content of about 25 to 70%, with respect to a baseline process employing only C₂H₂. And such AHM may have a terminal bond (e.g., including hydrogen (H), oxygen (O), nitrogen (N), metal (M), and/or a halogen (X)) content of about 0 to 21 at. %. Some studies of halocarbon deposited AHMs have shown an 8-32% decrease in etch rate when compared to the C₂H₂ baseline.

The halocarbon may be a hydrocarbon with at least one hydrogen atom and at least one halogen atom. In some implementations, the hydrogen and halogen content may be further tuned by addition of hydrogen (H₂) gas into the plasma. In such processes, hydrogen species may replace halogen species in the AHM. In some non-limiting processes, the hydrogen species and halogen species can be provided to a surface at temperatures below about 300° C. Additional halogen-containing precursors, organic reactants, and halogen-containing reactants are described herein.

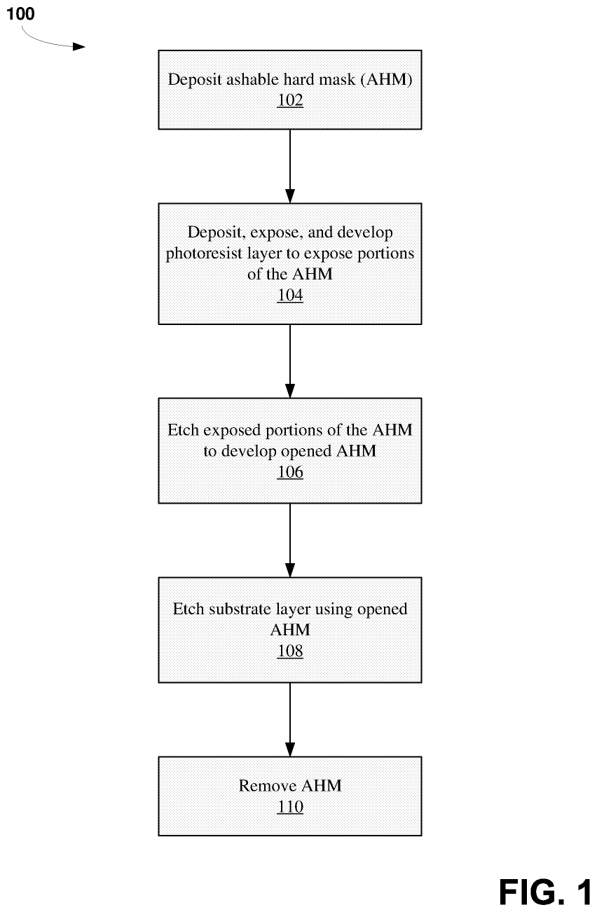

FIG. 1 is a process flow diagram 100 showing relevant operations of methods of using an AHM as a hard mask in etching operations. While the description below refers chiefly to semiconductor substrates, the methods may also be applied to layers on other types of substrates including glass substrates. Examples of materials that may be masked with the AHM include dielectric materials such as oxides (e.g., SiO₂) and nitrides (e.g., SiN and TiN), polysilicon (Poly-Si), and metals such as aluminum (Al), copper (Cu), and tungsten (W). In certain embodiments, the AHMs described herein are used to pattern oxides, nitrides, or polysilicon layers.

In operation 102, an ashable hard mask is deposited on the layer to be etched by plasma enhanced chemical vapor deposition (PECVD). PECVD processes involve generating plasma in the deposition chamber. In particular embodiments, a dual radio frequency (RF) plasma sources that include a high frequency (HF) power and a low frequency (LF) power may be used. In some processes, one or more AHM layers are deposited.

In operation 104, a photoresist layer is deposited, exposed, and developed in accordance with the desired etch pattern. In some implementations, an anti-reflective layer (ARL) may be deposited on the AHM film prior to photoresist deposition.

In operation 106, the AHM film is opened by etching the exposed portions of the AHM. Opening the AHM may be performed by a fluorine-rich dry etch.

Next, in operation 108, the substrate layer is selectively etched to transfer the pattern to the substrate layer. The selective etch may be performed such that the substrate layer is etched without substantially diminishing the AHM walls. Examples of etches can include radical and/or ionic-based etches. Examples of etch chemistries can include halogen-based etch chemistries such as fluorine-containing and chlorine-containing etch chemistries. For example, capacitively-coupled plasmas generated from fluorocarbon-containing process gases may be used to selectively etch oxide layers. Specific examples of process gases include CₓF_{y}-containing process gases, optionally with oxygen (O₂) and an inert gas, such as C₄H₈/CH₂F₂/O₂/Ar.

Lastly, in operation 110, a technique referred to as ashing, plasma ashing, or dry stripping is used to remove the AHM. Ashing may be performed by an oxygen-rich dry etch. Often, oxygen is introduced in a chamber under vacuum and RF power creates oxygen radicals in plasma to react with the AHM and oxidize it to water (H₂O), carbon monoxide (CO), and carbon dioxide (CO₂). Optionally, any remaining AHM residue may also be removed by wet or dry etching processes after ashing. The result is a patterned substrate layer.

As the depth and/or aspect ratios for HAR etching increase, the etch selectivity or thickness of the AHM must also increase. Etch selectivity can be determined by comparing the etch rate of the AHM layer to an underlying layer. The etch selectivity can sometimes be approximated by determining the hydrogen content, refractive index (RI, n), extinction coefficient (k), density, and modulus or rigidity of the AHM layer. Typically, an AHM having lower hydrogen content, lower RI, higher density, and higher modulus is able to withstand higher etch rates in an etch process involving ion bombardment. Therefore, AHMs with lower hydrogen content, lower RI, higher density, and/or higher modulus have a higher selectivity and lower etching rate, and thus can be used more efficiently and effectively for HAR semiconductor processes. The desired etch selectivity of the AHM may depend on the etching process and the composition of the underlying layers, but the correlation between etch selectivity and the material properties above remains the same regardless of the etching process or composition of the underlying layers. The selectivity correlations as described here applies to all types of underlying layers, including polysilicon layers, oxide layers, and nitride layers.

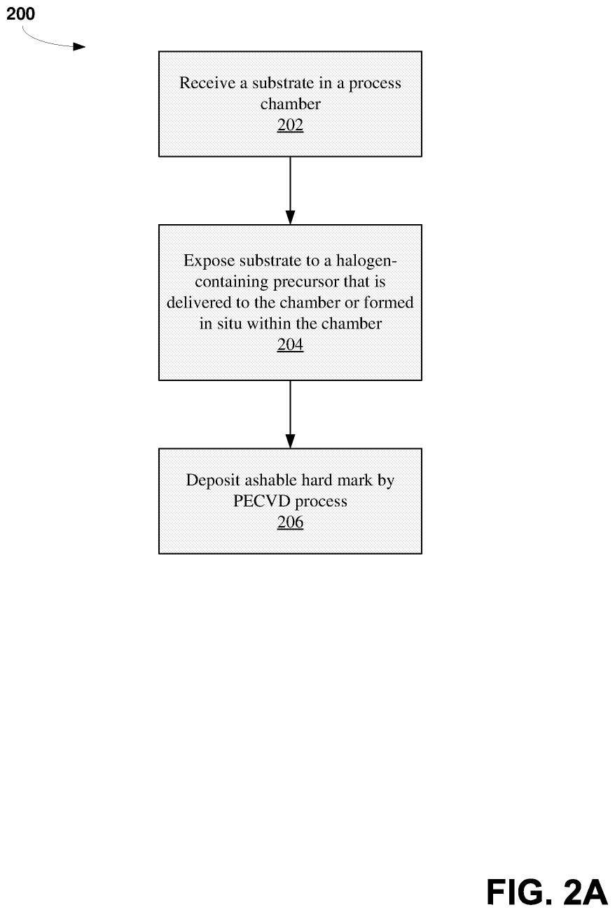

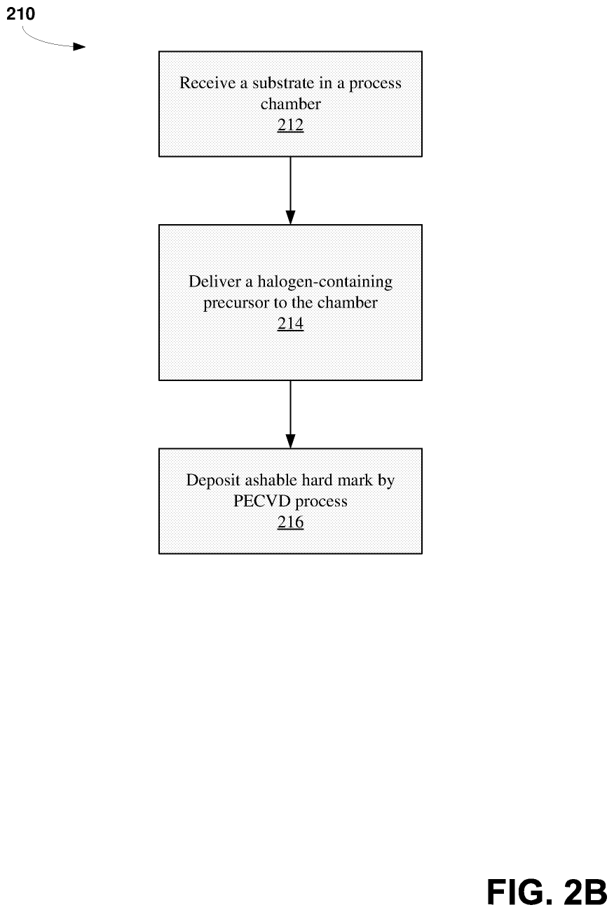

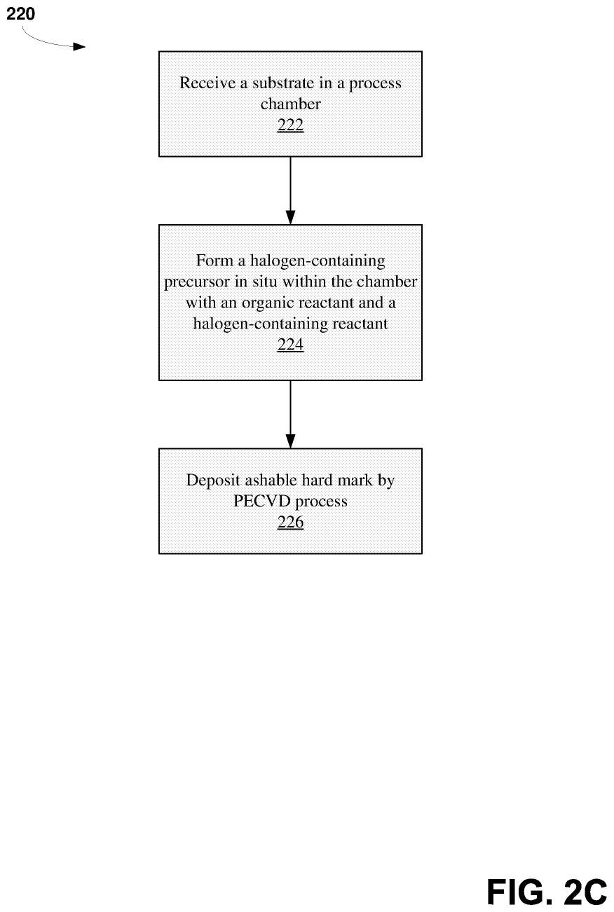

FIG. 2A shows a process flow diagram 200 showing relevant operations of methods of forming AHMs according to various embodiments. In operation 202, a substrate is received in a processing chamber. The substrate may be provided to the chamber in this operation, or the substrate may already be in the chamber from a prior operation.

In operation 204, the substrate is exposed to a halogen-containing precursor, which can be delivered to the chamber or formed in situ within the chamber. Next, in operation 206, an ashable hard mask is deposited on the substrate by a PECVD process. The PECVD process can include a single HF RF plasma source or a dual HF/LF RF plasma source to produce a plasma in the processing chamber. The result of operation 206 is an AHM film. Thereafter, the AHM film can be optionally treated, such as by annealing, etching, and/or ashing the film.

FIG. 2B shows a non-limiting process flow diagram 210 showing relevant operations. In operation 212, a substrate is received in a processing chamber. In operation 214, a halogen-containing precursor is delivered to the chamber, in which the precursor can be provided as process gas including the precursor and an inert gas carrier (e.g., any described herein). Next, in operation 216, an ashable hard mask is deposited on the substrate by a PECVD process, as described herein.

As described herein, the halogen-containing precursor can be formed in situ within the chamber. As seen in FIG. 2C, another non-limiting process flow diagram 220 shows operation 222 for receipt of a substrate in a processing chamber and operation 224 for in situ formation of the halogen-containing precursor. Operation 224 can include delivery of at least two reactants that can react to form the precursor. In one instance, the reactants can include an organic reactant (e.g., an alkane) with a halogen-containing reactant (e.g., HX, in which X is halogen). In particular, the combination of the reactants is selected to ensure that the reactants react with each other, such that halogen atoms are contained in a depositing species. Such reactants can be delivered as separate process gases. Next, in operation 226, an ashable hard mask is deposited on the substrate by a PECVD process, as described herein.

Any of the methods herein can be used to provide an AHM, including a multilayer stack including one or more AHM layers. For example, the multilayer stack can include a plurality of layers, in which at least one layer is an AHM layer. In some embodiments, the at least one layer is formed by using a halogen-containing precursor. In other embodiments, the at least one layer is formed by using a precursor or a reactant described herein, such as a halogen-containing precursor, a hydrocarbon precursor, an organic reactant, a halogen-containing reactant, a pure hydrocarbon reactant, a halocarbon reactant, a hydrocarbon reactant having a leaving group, an aliphatic moiety, an aromatic moiety, a carbocycle, a heterocycle, an elemental halogen, a hydrogen gas, a metal-containing reactant, or a combination of any of these.

Non-limiting examples of layers for a multilayer stack can include one or more of any of the following: an AHM layer, a carbon-containing layer, a metal-doped carbon-containing layer, a silicon-containing layer, a dielectric layer, a metal layer, a carbide layer, a nitride layer, an oxynitride layer, an oxycarbide layer, a metal carbide layer, a metal nitride layer, or others. Yet other non-limiting examples of layers can include carbon (e.g., amorphous carbon), metal-doped carbon, carbide, silicon nitride, silicon dioxide (SiO₂), silicon oxynitride, silicon carbide, silicon oxycarbide, titanium nitride, tungsten nitride, tantalum carbide, polysilicon (Poly-Si), aluminum, copper, and tungsten, including amorphous, hydrogenated, undoped, and/or doped forms thereof.

The multilayer stack can optionally include alternating layers of a first layer and a second layer. In some embodiments, at least one of the first or second layers includes a halogen. In other embodiments, at least one of the first or second layers is formed by using a halogen-containing precursor. In yet other embodiments, the first layer is formed by using a first halogen-containing precursor (e.g., in any of Embodiments 1-15 herein), and the second layer is formed by using another precursor or reactant (e.g., any described herein, such as a second halogen-containing precursor, a hydrocarbon precursor, an organic reactant, a halogen-containing reactant, a pure hydrocarbon reactant, a halocarbon reactant, a hydrocarbon reactant having a leaving group, an aliphatic moiety, an aromatic moiety, a carbocycle, a heterocycle, an elemental halogen, a hydrogen gas, a metal-containing reactant, or a combination of any of these).

### Process Mechanism

The presence of a halogen atom as a hydrogen getter, during deposition, provides an AHM film having lower hydrogen content. Without wishing to be limited to mechanism, there appears to be two processes involving such atoms: one in the gas phase and another in the deposited solid phase.

In the gas phase, halogen atoms may displace hydrogen atoms in some carbon-containing precursor fragments. The halogen-containing gas phase species are preferably radicals rather than ions, because ions may be accelerated deep into the deposited film, where it is more difficult to remove the halogen atoms (resulting in a film with overall a higher halogen content). Furthermore, these halogen-containing species can sequester hydrogen radicals from the plasma gas, thereby lowering the effective hydrogen content in the film and increasing the deposition rate. For instance, H radicals produce a competitive etch process during film growth, and total deposition rate is the difference between the H radical etch rate and the hydrocarbon radical deposition rate.

Apart from the gas phase mechanisms, there is a deposited phase mechanism in which halogen and/or hydrogen is abstracted from the growing film. Due to bond energy considerations, it is favorable to abstract halogen than hydrogen from the carbon matrix in the growing film. Thus, employing precursors that have some hydrogen atoms replaced with halogen atoms produces a net reduction of combined hydrogen and halogen within the film. The net impact of these two mechanisms is a lower hydrogen content.

An additional benefit of the addition of a halogen in the depositing species may be that C—X (where X is halogen) bonds are more kinetically available than most C—H bonds, thus allowing for thermal energy to drive down the halide content more quickly and at lower temperatures. This reduction in terminal bond species, C—H or C—X, shows an equal or higher deposition rate and a similar stress to modulus ratio as the current state of the art with a pure hydrocarbon precursor, e.g., C₂H₂ or C₃H₆.

In particular embodiments, the AHM film includes lower hydrogen content (e.g., less than about 15 at. % or even less than about 1 at. %) with a faster deposition rate and comparable stress to modulus ratio. Such films can exhibit improved etch rates, e.g., blanket etch rates that correlate well with pattern etch rates with an improvement by 8 to 30% over C₂H₂ baseline (e.g., an AHM deposited with C₂H₂ or C₃H₆ at 650° C.).

To obtain such benefits, the halogen atom should participate as a depositing species. For instance, the halogen-containing precursor, whether delivered directly or formed in situ, should participate as a depositing species. Without wishing to be limited by mechanism, the addition of a hydrogen abstraction mechanism by a halide radical may be accessible only when the precursor contains a species that is capable of abstraction and not as an additional, non-depositing, species. Deposition can occur with the halogen-containing precursor by itself or co-flowed with a pure hydrocarbon precursor, e.g., C₂H₂. Film hydrogen content improvement will occur for both single high-frequency and dual high- and low-frequency RF setup types.

The processes herein and their resultant films can be compared to any useful baseline, such as an AHM deposited with a precursor containing mostly or only C₂H₂. In one embodiment, the AHM film of the present disclosure employs a process described herein with any precursor or a reactant described herein (e.g., such as in paragraphs [0088]-[0124]). In particular embodiments, the AHM film of the present disclosure shows decreased hydrogen and halogen (H+X) content, as compared to the total hydrogen (H) content of a C₂H₂ baseline. In other embodiments, the AHM film of the present disclosure shows decreased H content, as compared to the total H content of a C₂H₂ baseline. Such a decrease can include a decrease of about 10% to 65% (e.g., about 10% to 20%, 10% to 25%, 10% to 30%, 10% to 35%, 10% to 40%, 10% to 45%, 10% to 50%, 10% to 55%, 10% to 60%, 15% to 20%, 15% to 25%, 15% to 30%, 15% to 35%, 15% to 40%, 15% to 45%, 15% to 50%, 15% to 55%, 15% to 60%, 15% to 65%, 20% to 25%, 20% to 30%, 20% to 35%, 20% to 40%, 20% to 45%, 20% to 50%, 20% to 55%, 20% to 60%, or 20% to 65%), as compared to the total H content of a C₂H₂ baseline. Such processes can include vapor deposition, including CVD or PECVD, at any useful deposition temperature (e.g., from 80° C. to 750° C., as well as other ranges described herein).

In one non-limiting embodiment, deposition with a halogen-containing precursor provides a decrease in hydrogen and halogen (H+X) content as expressed as a percent of the total H content of the C₂H₂ baseline from 20% to 80%. In particular embodiments, a decrease in H content from 30% to 80% is observed. In other embodiments, the decrease in H+X content or the decreased in H content is observed at a deposition temperature greater than about 500° C. or between about 500° C. to 750° C., as compared to an AHM deposited with C₂H₂ at the same temperature. In particular embodiments, deposition occurs by way of a PECVD process.

In one non-limiting embodiment, at all temperatures and under similar processing conditions to the C₂H₂ baseline, the deposition rate with a halogen-containing precursor that provides the AHM film of the present disclosure can be faster than or comparable to a deposition rate of the C₂H₂ baseline. In some embodiments, the overall stress to modulus ratio of the AHM film of the present disclosure is the same as the C₂H₂ baseline. In some embodiments, the AHM film of the present disclosure has a higher stress and a higher modulus, as compared to the C₂H₂ baseline.

The process herein can be further tuned to decrease the stress to comparable levels without increasing the H and/or X content (e.g., temperature, RF conditions, etc.). In one embodiment, stress can be decreased by increasing the total pressure of the process, decreasing LF, and/or increasing the partial pressure of the deposition species, such as the halogen-containing precursor, hydrocarbon precursor, organic reactant, halogen-containing reactant, pure hydrocarbon reactant, halocarbon reactant, hydrocarbon reactant having a leaving group, aliphatic moiety, aromatic moiety, carbocycle, heterocycle, elemental halogen, hydrogen gas, metal-containing reactant, or a combination of any of these

In certain non-limiting embodiments, the AHM film described herein possesses an H+X content that is below 10 at. %, 8 at. %, 5 at. %, or 3 at. %. In other embodiments, over all temperature conditions, the halogen-containing precursor provides an AHM film having a lower H and X content than the C₂H₂ baseline.

Furthermore, use of a hydrogen (H₂) gas during deposition can lower halogen content within the film in certain temperature ranges (e.g., a temperature below 300° C.). Such a process can include an addition of H₂ gas into the plasma, which may allow the hydrogen species to replace the halogen species in the AHM. In this way, halogen content can be lowered within the film by including H₂ gas into the plasma.

The AHM films of the present disclosure can exhibit improved etch rates. In some embodiments, the AHM film of the present disclosure provides an improved etch rate of about 5% to 40% (e.g., about 5% to 10%, 5% to 20%, 5% to 30%, 7% to 10%, 7% to 20%, 7% to 30%, 7% to 40%, 10% to 20%, 10% to 30%, 10% to 40%, 15% to 20%, 15% to 30%, or 15% to 40%), as compared to C₂H₂ baseline. A standard silicon oxide logic etch can be used as a test vehicle.

### Process Window

This section describes various process parameters that may be employed to produce AHM films. The process parameters are provided for a plasma enhanced chemical vapor deposition process that takes place in a processing chamber such as one described below.

The AHM film deposition methods described herein may be performed at any appropriate process temperature to obtain desired AHM characteristics, with example temperature of the pedestal ranging from about 80° C. to 750° C., 80° C. to 700° C., 80° C. to 650° C., 80° C. to 600° C., 80° C. to 550° C., 80° C. to 500° C., 80° C. to 450° C., 80° C. to 400° C., 80° C. to 350° C., 80° C. to 300° C., 80° C. to 250° C., 80° C. to 200° C., 80° C. to 150° C., 80° C. to 100° C., 85° C. to 750° C., 85° C. to 700° C., 85° C. to 650° C., 85° C. to 600° C., 85° C. to 550° C., 85° C. to 500° C., 85° C. to 450° C., 85° C. to 400° C., 85° C. to 350° C., 85° C. to 300° C., 85° C. to 250° C., 85° C. to 200° C., 85° C. to 150° C., 85° C. to 100° C., 90° C. to 750° C., 90° C. to 700° C., 90° C. to 650° C., 90° C. to 600° C., 90° C. to 550° C., 90° C. to 500° C., 90° C. to 450° C., 90° C. to 400° C., 90° C. to 350° C., 90° C. to 300° C., 90° C. to 250° C., 90° C. to 200° C., 90° C. to 150° C., 90° C. to 100° C., 95° C. to 750° C., 95° C. to 700° C., 95° C. to 650° C., 95° C. to 600° C., 95° C. to 550° C., 95° C. to 500° C., 95° C. to 450° C., 95° C. to 400° C., 95° C. to 350° C., 95° C. to 300° C., 95° C. to 250° C., 95° C. to 200° C., 95° C. to 150° C., 95° C. to 100° C., 100° C. to 750° C., 100° C. to 700° C., 100° C. to 650° C., 100° C. to 600° C., 100° C. to 550° C., 100° C. to 500° C., 100° C. to 450° C., 100° C. to 400° C., 100° C. to 350° C., 100° C. to 300° C., 100° C. to 250° C., 100° C. to 200° C., 150° C. to 750° C., 150° C. to 700° C., 150° C. to 650° C., 150° C. to 600° C., 150° C. to 550° C., 150° C. to 500° C., 150° C. to 450° C., 150° C. to 400° C., 150° C. to 350° C., 150° C. to 300° C., 150° C. to 250° C., 150° C. to 200° C., 200° C. to 750° C., 200° C. to 700° C., 200° C. to 650° C., 200° C. to 600° C., 200° C. to 550° C., 200° C. to 500° C., 200° C. to 450° C., 200° C. to 400° C., 200° C. to 350° C., 200° C. to 300° C., 200° C. to 250° C., 250° C. to 750° C., 250° C. to 700° C., 250° C. to 650° C., 250° C. to 600° C., 250° C. to 550° C., 250° C. to 500° C., 250° C. to 450° C., 250° C. to 400° C., 250° C. to 350° C., 250° C. to 300° C., 300° C. to 750° C., 300° C. to 700° C., 300° C. to 650° C., 300° C. to 600° C., 300° C. to 550° C., 300° C. to 500° C., 300° C. to 450° C., 300° C. to 400° C., 300° C. to 350° C., 350° C. to 750° C., 350° C. to 700° C., 350° C. to 650° C., 350° C. to 600° C., 350° C. to 550° C., 350° C. to 500° C., 350° C. to 450° C., 350° C. to 400° C., 400° C. to 750° C., 400° C. to 700° C., 400° C. to 650° C., 400° C. to 600° C., 400° C. to 550° C., 400° C. to 500° C., 400° C. to 450° C., 450° C. to 750° C., 450° C. to 700° C., 450° C. to 650° C., 450° C. to 600° C., 450° C. to 550° C., 450° C. to 500° C., 500° C. to 750° C., 500° C. to 700° C., 500° C. to 650° C., 500° C. to 600° C., 500° C. to 550° C., 550° C. to 750° C., 550° C. to 700° C., 550° C. to 650° C., 550° C. to 600° C., 600° C. to 750° C., 600° C. to 700° C., 600° C. to 650° C., 650° C. to 750° C., 650° C. to 700° C., or 700° C. to 750° C.

Depositing an AHM at higher temperatures, e.g., more than about 200° C. or 300° C., may improve the etch selectivity of the AHM. Process temperature can affect the stress, selectivity, and transparency at least in part due to sp² bond versus sp³ bond formation. Higher temperatures favor sp² rich amorphous carbon network formation as the high temperatures enable easy breakage of C—H bonds and subsequent diffusion of hydrogen. For example, films deposited at temperatures above about 200° C. may have significantly more sp² CH and CH₂ bonds and relatively fewer sp³ bonds, which have increased carbon content and higher density, and correlate with increased etch selectivity. AHM films deposited at lower temperatures, e.g., below about 175° C. may have less sp² bonding, compared to films deposited at higher temperatures.

In various embodiments, the temperature in the processing chamber, the substrate holder, and/or the pedestal can be at least about 50° C. In other embodiments, the temperature is at least about 500° C. or within a range of about 80° C. to 750° C., about 80° C. to 650° C., or about 550° C. to 650° C. The total pressure in the processing chamber can be between about 1 and 10 Torr or about 5 Torr.

Precursor delivery into the processing chamber can be conducted by using one or more gas inlets. Delivery can include use of one or more process gases, in which a single process gas can be used to deliver a halogen-containing precursor with an inert gas. In other embodiments, a plurality of process gases can be employed, such as a first process gas having an organic reactant with a first inert gas, as well as a second process gas having the halogen-containing reactant with a second inert gas. Upon delivery into the chamber, the organic reactant and halogen-containing reactant can react to form a halogen-containing precursor in situ.

In addition to delivery of a precursor species (e.g., a halogen-containing precursor, an organic reactant, or a halogen-containing reactant), a process gas can include other compounds. Such compounds can include hydrogen (H₂) gas, a hydrocarbon precursor (e.g., a hydrocarbon, such as C₂H₂ and any described herein, which can be halogenated or non-halogenated), and/or a metal-containing reactant (e.g., including W, Mo, Hf, B, Ru, or Co), in which delivery as a process gas can include one or more inert gases.

In some embodiments, the inert gas comprises at least about 10% or at least about 80% or at least about 95% by volume of all inert gas used. In other embodiments, the inert gas is helium (He), neon (Ne), argon (Ar), nitrogen (N₂), krypton (Kr), xenon (Xe), or any combination thereof.

Precursor gas volumetric flow rates depend on the particular process chamber, substrate, and other process conditions. Examples of volumetric flow rates that may be used for a single 300 mm substrate are between about 200 to 5500 sccm, between about 300 to 2500 sccm, or between about 400 to 2000 sccm, of total volumetric flow of precursor species and inert gas. In some embodiments, the volumetric flow is between about 300 to 5000 sccm or about 400 to 2000 sccm for an inert gas; and between about 1 to 500 sccm or about 20 to 100 sccm for a precursor species (e.g., a halogen-containing precursor, a hydrocarbon precursor, an organic reactant, or a halogen-containing reactant).

A ratio between the precursor species and the inert gas may be between about 0.01 and about 0.5. In some embodiments, the flow rate of the halogen-containing species is between about 1% and about 50% of the total flow rate and an inert gas comprises the rest of the total flow rate. In other embodiments, the flow rate of the halogen-containing species with a hydrocarbon precursor (e.g., C₂H₂) is between about 1% and about 50% of the total flow rate and an inert gas comprises the rest of the total flow rate.

Additional compounds can be provided at a volumetric flow that is between about 0 to 500 sccm, 1 to 500 sccm, 0 to 250 sccm, 1 to 250 sccm, about 0 to 50 sccm, or about 5 to 50 sccm. For instance, hydrogen (H₂) gas, hydrocarbon precursor (e.g., a hydrocarbon, such as C₂H₂), and/or a metal-containing reactant can be provided at such flow rates. In one embodiment, the hydrogen gas is provided at a flow rate of 0 to 500 sccm or 1 to 500 sccm. In another embodiment, the metal-containing reactant is provided at a flow rate of 0 to 250 sccm or 1 to 250 sccm. Unless otherwise specified, the flow rates disclosed herein are for a single station tool configured for 300 mm wafers. Flow rates generally scale linearly with the number of stations and substrate area.

Annealing may be performed at temperatures of about 500° C. or more. Annealing may be performed to reduce the hydrogen content of the film.

In some embodiments, low frequency (LF) RF power refers to an RF power having a frequency between about 200 kHz and 2 MHz. In some embodiments, LF RF power has a frequency of about 400 kHz. High frequency RF power refers to an RF power having a frequency between about 2 MHz and about 100 MHz. In some embodiments, HF RF power has a frequency of about 60 MHz, a frequency of about 27 MHz, or a frequency of about 13.56 MHz.

RF operation can include either continuous wave mode or pulsing mode. Pulsing can include synchronized pulsing of the HF and LF components, pulsing of the HF component with a continuous wave of the LF component, or a continuous wave of the HF component with pulsing of the LF component. Here, pulsing refers to having the power of the HF and/or LF at 0 W for the “off” portion of the pulsing cycle.

In some embodiments, the HF power may be between about 10 W and 8000 W per 300 mm wafer. In other embodiments, the LF power may vary between 0 W and 4000 W per 300 mm wafer. Either LF or HF plasma may be used alone. In other embodiments, LF and HF components are both present, in which the HF power is between about 10 W and 8000 W, and the LF power may be about 4000 W of less.

In many embodiments, the minimum power of the HF RF component and the minimum power of the LF RF component are sufficient to maintain a plasma. All powers provided herein are per 300 mm substrate. RF power as described herein generally scales linearly with number of stations and area of wafers. The power values may be represented on a per area basis, e.g., 2500 W may also be represented as 0.884 W/cm² for a 300 mm wafer.

In some embodiments, the substrate is disposed on a pedestal within the processing chamber and between the pedestal and a showerhead. A gap between the pedestal and the showerhead can be characterized by a microvolume, which can include but is not limited to volumes between 0.1 liter and 2 liters; and/or a distance, which can include but is not limited to distances between 0.2 inch to 2.5 inches or even up to 6 inches.

In some processes herein, the AHM film deposits at a rate of at least about 200 Å/min or about 400 Å/min or about 600 Å/min or about 1000 Å/min. In some embodiments, the AHM film deposits at a rate of between about 200 Å/min and about 5000 Å/min. The deposition rate of the AHM film may depend on the LF and HF power, chamber pressure, process temperature, and precursor species.

### Composition of Process Gas and Halogen-Containing Precursors

The methods and apparatuses in embodiments herein employ a halogen-containing precursor. Such a precursor can include any described herein, including reactants that can react together to form the halogen-containing precursor in situ within the chamber.

As used herein, a precursor species is used to broadly encompass compounds that form the AHM film. Thus, a precursor species can include a halogen-containing precursor, an organic reactant, a halogen-containing reactant, a pure hydrocarbon reactant, a halocarbon reactant, a hydrocarbon reactant having a leaving group, a hydrocarbon precursor, or a metal-containing reactant. Each of these species can provided as a process gas having an inert gas (e.g., any described herein, such as He, Ne, Ar, N₂, Kr, Xe, or any combination thereof).

The precursor species can include one or more compounds, meaning that any precursor species described herein can be used alone or in a combination. Such a combination can be provided within the same process gas or in different process gases that are introduced sequentially or simultaneously into the processing chamber. In some embodiments, the precursor species collectively include halogen, carbon, and hydrogen atoms (with optional other heteroatoms) in one or more compounds. In other embodiments, a precursor species can be used with an inert gas or with H₂ gas.

In Embodiment 1, the precursor species can include at least one hydrogen atom and at least one halogen atom. In particular embodiments, such a precursor species is a halogen-containing precursor. In some embodiments, the precursor species is characterized by a ratio of carbon atoms to hydrogen atoms (a C:H ratio) that is at least about 1:3 or possibly as high as 1:0; or between about 1:3 to 8:1 or between about 1:2 to 2:1. In other embodiments, the precursor species is characterized by a ratio of halogen atoms to hydrogen atoms (an X:H ratio) that is at least about 1:20 or possibly as high as 1:0; or between about 17:1 to 1:17 or about 3:3:1 to 1:3. Halogen atoms can include F, Cl, Br, and/or I.

The precursor species can be characterized by a number of carbon atoms in each compound. In some embodiments, the precursor species has 1-8 carbon atoms. In other embodiments, the precursor species include C₁₋₈ alkyl, C₂₋₈ alkenyl, C₂₋₈ alkynyl, C₅₋₈ aryl, C₁₋₈ haloalkyl, C₂₋₈ haloalkenyl, C₂₋₈ haloalkynyl, or C₅₋₈ haloaryl.

The precursor species can include any useful class of compounds. In certain embodiment, the precursor species can be or include a straight-chain or branched-chain aliphatic moiety, an aromatic moiety, a cycloaliphatic moiety, a multicycloaliphatic moiety comprising one or more halo substitutions.

Non-limiting aliphatic moieties can include C₁₋₁₀ aliphatic or C₁₋₈ aliphatic moieties. Embodiments of aliphatic moieties can include alkanes, alkenes, alkynes, aromatic compounds, cycloaliphatic compounds, and multicycloaliphatic compounds. Such moieties can include one or more halo substitutions provided on an sp² carbon, an spa carbon, a branched portion, an unbranched portion, or both a branched and unbranched portion. When at least one halo substitution is present, such precursor species can be a halocarbon (e.g., a compound have one or more halo and one or more carbon atoms), a haloaliphatic, a haloalkane, a haloalkene, a haloalkyne, a haloaromatic, or a halocarbocycle, as described herein.

Alkanes can include straight-chain alkanes or branched-chain alkanes. Such alkanes can be substituted with one type of halo atom (or mono-halo substituted). For instance, a mono-fluorine substituted alkane only includes fluorine as the halogen atom, but one or more fluorine atoms can be present within the alkane. Non-limiting mono-halogen substituted, straight-chain alkanes include a pure halocarbon (e.g., CₐX_{b}, in which X is halo, a is 1 to 10, and b is 2a+2; such as CF₄, CCl₄, CBr₄, or CI₄), 1,2-difluoroethane, 1,1-difluoroethane, 1,1-difluoroethane, 1-fluoropropane, 2-fluoropropane, 1,2-dichloroethane, 1,1-dichloroethane, 1-chloropropane, 2-chloropropane, 1,2-dibromoethane, 1,1-dibromoethane, 1-bromopropane, 2-bromopropane, 1,2-diiodoethane, 1,1-diiodoethane, 1-iodopropane, or 2-iodopropane. In particular embodiments, the straight-chain alkane includes a halo substitution at one or both terminal carbon atoms in the chain.

Branched-chain alkanes can include halo substitutions on a branched portion or an unbranched portion or on both branched and unbranched portions. Non-limiting branched alkanes include tert-butyl fluoride (2-fluoro-2-methylpropane), sec-butyl fluoride (2-fluorobutane), isobutyl fluoride (1-fluoro-2-methylpropane), tert-butyl chloride (2-chloro-2-methylpropane), sec-butyl chloride (2-chlorobutane), isobutyl chloride (1-chloro-2-methylpropane), tert-butyl bromide (2-bromo-2-methylpropane), sec-butyl bromide (2-bromobutane), isobutyl bromide (1-bromo-2-methylpropane), tert-butyl iodide (2-iodo-2-methylpropane), sec-butyl iodide (2-iodobutane), or isobutyl iodide (2-iodo-2-methylpropane). In particular embodiments, the branched-chain alkane includes a halo substitution at one or more terminal carbon atoms in the chain.

Alkenes can include straight-chain and branched-chain alkenes. Such alkenes can include one or more halo substitutions (e.g., on an sp² carbon, an sp³ carbon, a branched portion, an unbranched portion, on an sp² carbon of a branched portion, or on an sp² carbon of an unbranched portion). In some embodiments, a straight-chain alkene can include one or more halogen substitutions on the sp² carbon (e.g., cis-1,2-difluoroethene, trans-1,2-difluoroethene, 2,3-difluoro-2-butene, 1-fluoropropene, cis-1,2-dichloroethene, trans-1,2-dichloroethene, 2,3-dichloro-2-butene, 1-chloropropene, cis-1,2-dibromoethene, trans-1,2-dibromoethene, 2,3-dibromo-2-butene, 1-bromopropene, cis-1,2-diiodoethene, trans-1,2-diiodoethene, 2,3-diiodo-2-butene, or 1-iodopropene) or one or more halogen substitutions on the sp³ carbon for longer chains (e.g., 2,3-difluoro-1-butene, 2,3-dichloro-1-butene, 2,3-dibromo-1-butene, or 2,3-diiodo-1-butene). In particular embodiments, the straight-chain alkene includes a halo substitution at one or more terminal carbon atoms in the chain.

In other embodiments, the branched-chain alkene can include an sp² carbon on the branch portion (e.g., and include at least one halo substitution on an sp² carbon; or at least one halo substitution on an sp³ carbon; or at least one halo substitution on an sp² carbon and at least one halo substitution on an sp³ carbon) and/or an sp² carbon on the unbranched portion for longer chains (e.g., and include at least one halo substitution on an sp² carbon; or at least one halo substitution on the sp³ carbon; or at least one halo substitution on an sp² carbon and at least one halo substitution on sp³ carbon).

Alkynes can include straight-chain and branched-chain alkynes. Such alkynes can include one or more halo substitutions (e.g., on an sp carbon, an sp² carbon, an sp³ carbon, a branched portion, an unbranched portion, on an sp carbon of a branched portion, or on an sp carbon of an unbranched portion). A straight-chain alkyne can include at least one halo substitution on an sp carbon; or at least one halo substitution on an sp³ carbon for longer chains. A branched-chain alkyne can include an sp carbon on the branch portion (e.g., and include at least one halo substitution on an sp carbon; or at least one halo substitution on an sp³ carbon; or at least one halo substitution on an sp carbon and at least one halo substitution on an sp³ carbon) and/or an sp carbon on the unbranched portion for longer chains (e.g., and include at least one halo substitution on an sp carbon; or at least one halo substitution on the sp³ carbon; or at least one halo substitution on an sp² carbon and at least one halo substitution on sp³ carbon).

Aromatics include any described herein, including those having single rings (e.g., benzene) or multiple rings (e.g., naphthalene). Aromatics can include at least on halo substitution on a carbon within a ring and/or on a carbon within an aliphatic substitution disposed on the ring. Non-limiting halo substitutions on the ring include monohalo substitutions, such as fluorobenzene, chlorobenzene, bromobenzene, iodobenzene, fluoronaphthalene, chloronaphthalene, bromonaphthalene, iodonaphthalene, 1,4-fluorobenzene, 1,3-difluorobenzene, 1,2-difluorobenzene, 1,4-dichlorobenzene, 1,3-dichlorobenzene, 1,2-dichlorobenzene, 1,4-dibromobenzene, 1,3-dibromobenzene, 1,2-dibromobenzene, 1,4-diiodobenzene, 1,3-diiodobenzene, 1,2-diiodobenzene, and analogs thereof. The aromatic can also include one or more aliphatic or haloaliphatic substitutions (e.g., alkyl, alkenyl, alkynyl, haloalkyl, haloalkenyl, or haloalkynyl). In some embodiments, the ring and/or the aliphatic substitution of the aromatic can include one or more halo substitutions. Non-limiting aliphatic-substituted aromatics with at least one halo substitution include those having one or more halo substitutions on a ring portion (e.g., 3-fluorotoluene, 2-fluorotoluene, 4-fluorotoluene, 3-chlorotoluene, 2-chlorotoluene, 4-chlorotoluene, 3-bromotoluene, 2-bromotoluene, 4-bromotoluene, 3-iodotoluene, 2-iodotoluene, or 4-iodotoluene); or one or more halo substitutions on an aliphatic portion attached to the ring (e.g., benzylfluoride, benzylchloride, benzylbromide, or benzyliodide); or at least one halo substitution on the aromatic portion and at least one halo substitution on aliphatic portion (e.g., 2,4-difluorobenzylfluoride, 4-fluorobenzylfluoride, 2,4-dichlorobenzylchloride, 4-chlorobenzylchloride, 2,4-dibromobenzylbromide, 4-bromobenzylbromide, 2,4-diiodobenzyliodide, or 4-iodobenzyliodide).

Carbocycles can include monocycloaliphatic or multicycloaliphatic moieties. Such carbocycles can include one or more halo substitutions, and cyclic groups can be saturated or unsaturated. Saturated carbocycles can include C₃₋₆ cycloaliphatic moieties, in which at least one halo substitution is present on the ring portion (e.g., fluorocyclobutane, chlorocyclobutane, bromocyclobutane, iodocyclobutane, fluorocyclopropane, chlorocyclopropane, bromocyclopropane, iodocyclopropane, fluorocyclopentane, chlorocyclopentane, bromocyclopentane, or iodocyclopentane); or at least one halo substitution on an aliphatic chain attached to the ring (e.g., (fluoromethyl)cyclobutene, (fluoromethyl)cyclopropane, (chloromethyl)cyclobutene, (chloromethyl)cyclopropane, (bromomethyl)cyclobutene, (bromomethyl)cyclopropane, (iodomethyl)cyclobutene, (iodomethyl)cyclopropane, etc.); or at least one halo substitution on the ring and at least one halo substitution on an aliphatic chain attached to the ring. Unsaturated carbocycles can include at least one halo substitution is present on the ring portion (e.g., 3-fluorocyclobutene, 3-chlorocyclobutene, 3-bromocyclobutene, or 3-iodocyclobutene); or at least one halo substitution on an aliphatic chain attached to the ring; or at least one halo substitution on the ring and at least one halo substitution on an aliphatic chain of the ring.

Carbocycles can include a plurality of ring portions. Such multicyclic moieties can be saturated (e.g., as in norbornane or derivatives thereof), which can include at least one halo substitution on a ring portion (e.g., 1-fluoro-norbornane, 2-fluoro-norbornane, 1-chloro-norbornane, 2-chloro-norbornane, 1-bromo-norbornane, 2-bromo-norbornane, 1-iodo-norbornane, or 2-iodo-norbornane), or at least one halo substitution on an aliphatic chain attached to the ring (e.g., 2-(fluoromethyl)norbornane, 2-(chloromethyl)norbornane, 2-(bromomethyl)norbornane, or 2-(iodomethyl)norbornane), or at least one halo substitution on the ring and at least one halo substitution on the aliphatic chain of the ring (e.g., 2-fluoro-3-(fluoromethyl)norbornane, 2-chloro-3-(chloromethyl)norbornane, 2-bromo-3-(bromomethyl) norbornane, or 2-iodo-3-(iodomethyl)norbornane); or unsaturated (e.g., as in norbornene or derivatives thereof), which can include at least one halo substitution on a ring portion (e.g., 2-fluoro-2-norbornene, 2-chloro-2-norbornene, 2-bromo-2-norbornene, or 2-iodo-2-norbornene), or at least one halo substitution on an aliphatic chain attached to the ring (e.g., 2-fluoromethyl-2-norbornene, 2-chloromethyl-2-norbornene, 2-bromomethyl-2-norbornene, or 2-iodomethyl-2-norbornene), or at least one halo substitution on the ring and at least one halo substitution on the aliphatic chain of the ring.

In any precursor herein, a single type of halo can be present (e.g., fluoro, chloro, bromo, or iodo). In other precursors, two or more different halo substitutions can be present.

In Embodiment 2, the precursor species can include a mixture of at least one halogen-containing precursor and at least one hydrocarbon precursor. In particular embodiments, the mixture includes a halo-containing precursor (e.g., halocarbon, a haloaliphatic, a haloalkane, a haloalkene, a haloalkyne, a haloaromatic, or a halocarbocycle) and a hydrocarbon precursor (e.g., an unsubstituted aliphatic, alkane, alkene, alkyne, aromatic, or carbocycle). The halogen-containing precursor can include any described herein, such as a halocarbon, as well as those described for Embodiment 1 above (paragraphs [0091]-[0103]). In particular embodiments, the halogen-containing precursor has a C:H ratio of at least about 1:3 and/or an X:H ratio of at least about 1:20; and the hydrocarbon precursor has a C:H ratio of at least 1:2.

Yet other non-limiting hydrocarbon precursors are described herein and can include an alkane, alkene, alkyne, aromatic, carbocycle, etc. In particular embodiments, the hydrocarbon precursor includes only hydrogen and carbon atoms, which can be saturated, unsaturated, straight-chain, branched-chain, or aromatic. In some embodiments, the hydrocarbon precursor is CₓH_{y}, wherein x is an integer between 2 and 10, and y is an integer between 2 and 24, including methane (CH₄), acetylene (C₂H₂), ethylene (C₂H₄), propylene (C₃H₆), butane (C₄H₁₀), butene (C₄H₈), cyclobutane (C₄H₈), cyclohexane (C₆H₁₂), benzene (C₆H₆), toluene (C₇H₈), norbornane (C₇H₁₂), or norbornene (C₇H₁₀). In some embodiments, two or more hydrocarbon precursors may be used. Any of these hydrocarbon precursors can be employed with one or more halogen-containing precursor (e.g., any described herein, such as a halocarbon, as well as those described for Embodiment 1 above in paragraphs [0091]-[0103]).

In Embodiment 3, the precursor species can include a mixture of an organic reactant with a halogen-containing reactant, in which the reactants can react to form in situ at least one halogen-containing precursor that can be deposited as a film. The organic reactant can be any carbon-containing compound that reacts with the halogen-containing reactant. Each of the organic reactant and the halogen-containing reactant can be provided as separate process gases, in which such process gases can delivered sequentially or simultaneously to the processing chamber.

The halogen-containing reactant can be any that reacts with an organic reactant (e.g., a C—H bond, an spa carbon, an sp² carbon, or an sp carbon). Non-limiting halogen-containing reactants include a halide (e.g., HX, in which X is halo, such as HF, HCl, HBr, or HI), elemental halogen or a halogen gas (e.g., F₂, Cl₂, Br₂, or I₂), a tetrahalosilane (e.g., SiX₄, in which each X is, independently, halo), a trihalosilane (e.g., SiX₃H, in which each X is, independently, halo), a dihalosilane (e.g., SiX₂H₂, in which each X is, independently, halo), a monohalosilane (e.g., SiXH₃, in which X is halo), or a Grignard reagent (e.g., R—Mg—X, in which R is optionally substituted alkyl, aliphatic, heteroalkyl, heteroaliphatic, aryl, or aromatic; and X is halo)

In Embodiment 4, the precursor species can include a mixture of a pure hydrocarbon reactant with a halogen-containing reactant, in which the reactants can react to form in situ at least one halogen-containing precursor that can be deposited as a film. Non-limiting pure hydrocarbon reactants include any described herein, e.g., such as in Embodiment 2 above in paragraphs [0104]-[0105]. Halogen-containing reactants can be any described herein, e.g., such as in Embodiment 3 above in paragraphs [0106]-[0107].

In Embodiment 5, the precursor species can include a mixture of a halocarbon reactant with a halogen-containing reactant, in which the reactants can react to form in situ at least one halogen-containing precursor that can be deposited as a film. Non-limiting halocarbon reactants include any described herein, e.g., such as in Embodiment 1 above in paragraphs [0091]-[0103]. Halogen-containing reactants can be any described herein, e.g., such as in Embodiment 3 above in paragraphs [0106]-[0107].

In Embodiment 6, the precursor species can include a mixture of a hydrocarbon reactant having a leaving group with a halogen-containing reactant, in which the reactants can react to form in situ at least one halogen-containing precursor that can be deposited as a film. Halogen-containing reactants can be any described herein, e.g., such as in Embodiment 3 above in paragraphs [0106]-[0107]. In use, the halogen-containing reactant can displace the leaving group, thereby providing a halogen-containing precursor that is formed in situ and that includes a hydrocarbon portion (from the hydrocarbon reactant with a leaving group) with a halogen portion (from the halogen-containing reactant).

Examples of a hydrocarbon reactant having a leaving group includes an alkane, alkene, alkyne, aromatic, or carbocycle having at least one leaving group. Non-limiting leaving groups include a halosulfonyl group (e.g., —OS(O)X, in which X is halo); a sulfonate group (e.g., —OS(O)₂R, in which R is halo, optionally substituted alkyl, optionally substituted heteroalkyl, optionally substituted alkoxy, optionally substituted haloalkyl, optionally substituted aryl, or optionally substituted haloaryl); a cyano group (—CN group); a nitrous oxide group (—N₂O); or a nitrate group (—ONO₂). Yet other non-limiting leaving groups include halo, triflate, mesylate, tosylate, brosylate, nosylate, or tresylate.

Other hydrocarbon reactants having the leaving group include an alkyl sulfonyl halide (e.g., Ak-OS(O)X, in which Ak is optionally substituted alkyl or aliphatic and X is halo), an aryl sulfonyl halide (e.g., Ar—OS(O)X, in which Ar is optionally substituted aryl or aromatic and X is halo), an alkyl triflate (e.g., Ak-OTf, in which Ak is optionally substituted alkyl or aliphatic), an aryl triflate (e.g., Ar-OTf, in which Ar is optionally substituted aryl or aromatic), an alkyl mesylate (e.g., Ak-OMs, in which Ak is optionally substituted alkyl or aliphatic), an aryl mesylate (e.g., Ar-OMs, in which Ar is optionally substituted aryl or aromatic), an alkyl tosylate (e.g., Ak-OTs, in which Ak is optionally substituted alkyl or aliphatic), an aryl tosylate (e.g., Ar-OTs, in which Ar is optionally substituted aryl or aromatic), a cyanoalkane (e.g., Ak-CN, in which Ak is optionally substituted alkyl or aliphatic), a cyanoaromatic (e.g., Ar—CN, in which Ar is optionally substituted aryl or aromatic), an alkyl nitrate (e.g., Ak-ONO₂, in which Ak is optionally substituted alkyl or aliphatic), or an aryl nitrate (e.g., Ar—ONO₂, in which in which Ar is optionally substituted aryl or aromatic).

In Embodiment 7, the precursor species can include a mixture of an aliphatic moiety with a halogen-containing reactant, in which the reactants can react to form in situ at least one halogen-containing precursor that can be deposited as a film. Non-limiting aliphatic moieties include any described herein, e.g., such as an alkane, alkene, alkyne, as well as any in Embodiment 1 above in paragraphs [0091]-[0103]. Halogen-containing reactants can be any described herein, e.g., such as in Embodiment 3 above in paragraphs [0106]-[0107].

In Embodiment 8, the precursor species can include a mixture of an aromatic moiety with a halogen-containing reactant, in which the reactants can react to form in situ at least one halogen-containing precursor that can be deposited as a film. Non-limiting aromatic moieties include any described herein, e.g., such as an aromatic having a single ring or multiple rings, as well as any in Embodiment 1 above in paragraphs [0091]-[0103]. Halogen-containing reactants can be any described herein, e.g., such as in Embodiment 3 above in paragraphs [0106]-[0107].

In Embodiment 9, the precursor species can include a mixture of a carbocycle with a halogen-containing reactant, in which the reactants can react to form in situ at least one halogen-containing precursor that can be deposited as a film. Non-limiting carbocycles include any described herein, e.g., such as a carbocycle having a single saturated ring, a single unsaturated ring, multiple saturated rings, multiple unsaturated rings, multiple rings that are a combination of saturated and unsaturated rings; a carbocycle that is a Diels-Alder product, in which the product can be a single ring or multiple rings having at least one unsaturated bond; as well as any in Embodiment 1 above in paragraphs [0091]-[0103] Halogen-containing reactants can be any described herein, e.g., such as in Embodiment 3 above in paragraphs [0106]-[0107].

In Embodiment 10, the precursor species can include a mixture of a heterocycle reactant with a halogen-containing reactant, in which the reactants can react to form in situ at least one halogen-containing precursor that can be deposited as a film. Non-limiting heterocycles include any described herein, e.g., such as a heterocycle having a single saturated ring, a single unsaturated ring, multiple saturated rings, multiple unsaturated rings, multiple rings that are a combination of saturated and unsaturated rings; or a heterocycle that is a Diels-Alder product, in which the product can be a single ring or multiple rings having at least one unsaturated bond. Halogen-containing reactants can be any described herein, e.g., such as in Embodiment 3 above in paragraphs [0106]-[0107].

In Embodiment 11, the precursor species can include a mixture of a pure hydrocarbon reactant with elemental halogen (e.g., X₂, in which X is halo), in which the reactants can react to form in situ at least one halogen-containing precursor that can be deposited as a film. Non-limiting pure hydrocarbon reactants include any described herein, e.g., such as in Embodiment 2 above in paragraphs [0104]-[0105].

In Embodiment 12, the precursor species can include a mixture of a halocarbon reactant with elemental halogen (e.g., X₂, in which X is halo), in which the reactants can react to form in situ at least one halogen-containing precursor that can be deposited as a film. Non-limiting halocarbon reactants include any described herein, e.g., such as in Embodiment 1 above in paragraphs [0091]-[0103].

In Embodiment 13, any of the precursor species in Embodiments 1-12 can be further used with one or more hydrocarbon precursors. In some embodiments, the hydrocarbon precursor has a C:H ratio of at least 1:2. In some embodiments the hydrocarbon precursor comprises compounds having a molecular weight of at most about 50 g/mol. Yet other non-limiting hydrocarbon precursors are described herein and can include an alkane, alkene, alkyne, aromatic, carbocycle, etc. In particular embodiments, the hydrocarbon precursor includes only hydrogen and carbon atoms, which can be saturated, unsaturated, straight-chain, branched-chain, or aromatic. In some embodiments, the hydrocarbon precursor is a hydrocarbon. Non-limiting hydrocarbons include CxHy, wherein x is an integer between 2 and 10, and y is an integer between 2 and 24, including methane, acetylene, ethylene, propylene, butane, butene, cyclobutane, cyclohexane, benzene, toluene, norbornane, or norbornene. In some embodiments, two or more hydrocarbon precursors may be used. The hydrocarbon precursor can be halogenated or non-halogenated. In certain embodiments, the hydrocarbon precursor is a halogenated hydrocarbon, where one or more hydrogen atoms are replaced by a halogen, particularly fluorine, chlorine, bromine, and/or iodine.

In Embodiment 14, any of the precursor species in Embodiments 1-13 can be further used with a hydrogen gas. In particular, the hydrogen gas can be introduced during exposure of the precursor species to the substrate, before the PECVD process, or during deposition by way of the PECVD process.

In Embodiment 15, any of the precursor species in Embodiments 1-14 can be further used with a metal-containing reactant, in which the metal-containing reactant can react with the halogen-containing precursor and can be deposited as a film. In some embodiments, the metal-containing reactant is employed to produce a metal-doped AHM film. In particular embodiments, the metal-containing reactant is employed with a halocarbon, a hydrocarbon reactant having a leaving group, a heterocycle reactant, or a halogen-containing precursor.

Non-limiting metal reactants include an organometallic reagent, a metal halide, or a metal hydride having one or more metal or metalloid atoms. Metal or metalloid atoms can include a transition metal or a metalloid, e.g., tungsten (W), molybdenum (Mo), hafnium (Hf), boron (B), ruthenium (Ru), or cobalt (Co). Examples of metal reactants include MₘXₙ or MₘRₚ or MₘXₙRₚ, in which M is W, Mo, Hf, B, Ru, or Co; m is an integer from 1 to 3; each of n and p is, independently, an integer from 1 to 8; each X is, independently, halo or H; and each R is, independently, H, halo, optionally substituted alkyl, optionally substituted aryl, a neutral ligand, an anionic ligand, or a multidentate ligand (e.g., a bidentate ligand).

Non-limiting ligands include an optionally substituted amine (e.g., NR₃ or R₂N-Ak-NR₂, in which each R can be, independently, H, optionally substituted alkyl, optionally substituted aliphatic, or optionally substituted aryl, and Ak is optionally substituted divalent form of alkyl), an optionally substituted phosphine (e.g., PR₃ or R₂P-Ak-PR₂, in which each R can be, independently, H, optionally substituted alkyl, optionally substituted aliphatic, or optionally substituted aryl, and Ak is optionally substituted divalent form of alkyl), an optionally substituted ether (e.g., OR₂, in which each R can be, independently, H, optionally substituted alkyl, optionally substituted aliphatic, or optionally substituted aryl), an optionally substituted alkyl, an optionally substituted alkyne, an optionally substituted benzene, oxo, carbon monoxide (CO), a diketonate (e.g., acetylacetonate (acac) or —OC(R¹)-Ak-(R¹)CO— or —OC(R¹)—C(R²)—(R¹)CO—), an aromatic (e.g., —Ar—), a cyclopentadienyl (e.g., —Cp, including substituted forms thereof, such as substitutions provided herein for alkyl or aryl), a pyrazolate, an optionally substituted heterocyclyl, an optionally substituted multivalent form of alkyl, or an optionally substituted multivalent form of heteroalkyl. In particular embodiments, each R¹ is, independently, H, optionally substituted alkyl, optionally substituted haloalkyl, or optionally substituted aryl; and each R² is, independently, H or optionally substituted alkyl; Ak is an optionally substituted divalent form of alkyl; and Ar is an optionally substituted divalent form of aryl.

Examples of metal-containing reactants can include WX₆, WR₄, WR₅, WR₆, MoX₂R₂, MoR₅, MoR₆, HfX₄, HfR₃, HfR₄, B₂X₆, BR₃, RuR₂, RuR₄, CoR₂, or CoX₆, in which each X is, independently, H or halo; and in which each R is, independently, H, halo, optionally substituted alkyl, optionally substituted aryl, a neutral ligand, an anionic ligand, or a multidentate ligand (e.g., a bidentate ligand).

### Film Properties

AHM films produced in accordance with the disclosed methods are typically composed primarily of carbon and hydrogen and optionally some halogen, but other elements may be present in the film (e.g., such as a dopant). Generally, the lower the atomic percent of hydrogen in the AHM, the higher the modulus and selectivity. Examples of other elements that may be present in the AHM film include a halogen, nitrogen, sulfur, boron, oxygen, tungsten, molybdenum, hafnium, boron, ruthenium, cobalt, titanium, and aluminum. Typically, such other elements are present in amounts not greater than about 20 atomic percent (at. %), 15 at. %, or 10 at. %.

By using a halogen-containing precursor, the AHM film can possess low hydrogen content. In some embodiments, the hydrogen content is at most about 5 at. % or about 4 at. %. In other embodiments, the hydrogen content is less than about 15 at. %, 10 at. %, 5 at. %, or 1 at. %. In other embodiments, hydrogen content is about 0.5 at. % to 20 at. %, 0.5 at. % to 15 at. %, 0.5 at. % to 10 at. %, 0.5 at. % to 5 at. %, 1 at. % to 20 at. %, 1 at. % to 15 at. %, 1 at. % to 10 at. %, 1 at. % to 5 at. %, 1.5 at. % to 20 at. %, 1.5 at. % to 15 at. %, 1.5 at. % to 10 at. %, 1.5 at. % to 5 at. %, 2 at. % to 20 at. %, 2 at. % to 15 at. %, 2 at. % to 10 at. %, 2 at. % to 5 at. %, 2.5 at. % to 20 at. %, 2.5 at. % to 15 at. %, 2.5 at. % to 10 at. %, 2.5 at. % to 5 at. %, 3 at. % to 20 at. %, 3 at. % to 15 at. %, 3 at. % to 10 at. %, 3 at. % to 5 at. %, 3.5 at. % to 20 at. %, 3.5 at. % to 15 at. %, 3.5 at. % to 10 at. %, 3.5 at. % to 5 at. %, 4 at. % to 20 at. %, 4 at. % to 15 at. %, 4 at. % to 10 at. %, or 4 at. % to 5 at. %.

While halogen can be present within the processing chamber, halogen content can be at most about 25 at. % or at most about 15 at. %. In other embodiments, the halogen content is about 0.1 at. % to 2 at. % or about 0 at. % to 25 at. %, including from about 0 at. % to 1 at. %, 0 at. % to 1.5 at. %, 0 at. % to 2 at. %, 0 at. % to 3 at. %, 0 at. % to 4 at. %, 0 at. % to 5 at. %, 0 at. % to 8 at. %, 0 at. % to 10 at. %, 0 at. % to 12 at. %, 0 at. % to 15 at. %, 0 at. % to 18 at. %, 0 at. % to 20 at. %, 0 at. % to 22 at. %, 0.1 at. % to 1 at. %, 0.1 at. % to 1.5 at. %, 0.1 at. % to 2 at. %, 0.1 at. % to 3 at. %, 0.1 at. % to 4 at. %, 0.1 at. % to 5 at. %, 0.1 at. % to 8 at. %, 0.1 at. % to 10 at. %, 0.1 at. % to 12 at. %, 0.1 at. % to 15 at. %, 0.1 at. % to 18 at. %, 0.1 at. % to 20 at. %, 0.1 at. % to 22 at. %, or 0.1 at. % to 25 at. %.

The combination of hydrogen and halogen can be present at an amount of less than about 35 at. % or at most about 7 at. %. In other embodiments, the combination of hydrogen and halogen can be about 1 at. % to 40 at. %, such as 1 at. % to 35 at. %, 1 at. % to 30 at. %, 1 at. % to 25 at. %, 1 at. % to 20 at. %, 1 at. % to 15 at. %, 1 at. % to 10 at. %, 2 at. % to 40 at. %, 2 at. % to 35 at. %, 2 at. % to 30 at. %, 2 at. % to 25 at. %, 2 at. % to 20 at. %, 2 at. % to 15 at. %, 2 at. % to 10 at. %, 3 at. % to 40 at. %, 3 at. % to 35 at. %, 3 at. % to 30 at. %, 3 at. % to 25 at. %, 3 at. % to 20 at. %, 3 at. % to 15 at. %, 3 at. % to 10 at. %, 4 at. % to 40 at. %, 4 at. % to 35 at. %, 4 at. % to 30 at. %, 4 at. % to 25 at. %, 4 at. % to 20 at. %, 4 at. % to 15 at. %, 4 at. % to 10 at. %, 5 at. % to 40 at. %, 5 at. % to 35 at. %, 5 at. % to 30 at. %, 5 at. % to 25 at. %, 5 at. % to 20 at. %, 5 at. % to 15 at. %, 5 at. % to 10 at. %, 10 at. % to 40 at. %, 10 at. % to 35 at. %, 10 at. % to 30 at. %, 10 at. % to 25 at. %, 10 at. % to 20 at. %, or 10 at. % to 15 at. %.

Carbon content can be at least about 90 at. %, 91 at. %, 92 at. %, 93 at. %, 94 at. %, 95 at. %, 96 at. %, 97 at. %, 98 at. %, 99 at. %, or more.

In addition to low hydrogen content, in some instances, the AHM film can be characterized by high modulus and/or low stress. Without wishing to be limited by mechanism, modulus is one non-limiting proxy for determining sp³ content, and a higher modulus is favored to promote etch selectivity. Stress is one non-limiting proxy for C—C bond strain, and a lower stress is favored. In some embodiments, the film has an sp² content of about 75% to 95%; and/or a modulus of at least about 50 GPa or at least about 70 GPa. In other embodiments, the AHM film has an elastic modulus of about 50 to 190 GPa or about 60 to 190 GPa. For a non-doped AHM film, the film can have an internal stress magnitude of at most about −1000 MPa, or between about −150 to −1000 MPa or about −200 to −1000 MPa (a negative internal stress denotes a compressive stress, such that lower values have less internal stress). For metal-doped AHM films, the film can have an internal stress magnitude of at most about 1000 MPa (a positive internal stress denotes a tensile stress) or a stress between about −500 MPa to 1000 MPa.

In some embodiments, the AHM film has a hardness of at least about 5 GPa or at least about 10 GPa. In other embodiments, hardness is between about 5 GPa and about 24 GPa. In some embodiments, the AHM film has a density of at least about 1.7 g/cm³, or between about 1.7 g/cm³ and about 2.3 μm/cm³.

In some embodiments the thickness of an AHM film deposited in accordance with methods disclosed herein is at least about 1 μm or at least about 2 μm or between about 1 μm and about 3.5 μm. Generally, the desired thickness of an AHM film may vary depending on the thickness of the underlying layers to be etched and the etch selectivity of the AHM, with thicker underlying layers to be etched requiring a thicker AHM. As discussed above, AHM films are used to etch a variety of underlying materials, and may have a different etch selectivity for each material. Etch selectivity of an AHM can be represented as a ratio of the etch rate of a material and the etch rate of the AHM, and may vary for different materials and etch chemistries.

In some embodiments, the AHM film has a normalized etch amount of about 0.6 to 1.0 or about 0.6 to 0.8. The normalized etch amount can be normalized to a standard, such as an AHM film deposited at 650° C. (650° C. AHM). A normalized etch amount can also be interpreted as a percentage, in which a normalized etch amount of 0.8 provides a process that will be etched 20% slower than the standard, such as a 650° C. AHM during blanket etch.

In some embodiments, an AHM film produced in accordance with the methods described herein has a refractive index (n or RI) at 633 nm of at least 1.8, or between about 1.80 to 2.70 or between about 2.3 to 2.6. Refractive index can generally be used as a proxy for the selectivity of the material, with higher refractive index indicating higher selectivity of an AHM. In some embodiments, an AHM film produced in accordance with the methods described herein has an extinction coefficient (k) at 633 nm of at most about 1.1, or between about 0.5 to 1.3 or between about 0.8 to 1.1.

### Applications

AHMs are typically used for creating features of electronic devices such as integrated circuits by etching one or more underlying layers of a substrate. Materials that may be etched using an AHM may include silicon (single crystal, polysilicon, or amorphous silicon), silicon oxide, silicon nitride, and tungsten. In some embodiments multiple layers are stacked and etched using a single AHM. Examples of such stacks include a layer of silicon and a layer of silicon oxide, and a layer of tungsten and a layer of silicon nitride. In some embodiments a stack includes repeating layers that are etched using a single AHM. Examples of such repeating layers include repeating layers of silicon oxide/polysilicon (OPOP) or of silicon oxide and silicon nitride (ONON). Front end of line and back end of line features may be etched using an AHM as disclosed herein. Memory or logic device features may be patterned. Examples of memory devices include: DRAM, NAND, and 3D NAND.

Typically, an AHM having lower hydrogen content, lower RI, higher density, lower stress, and/or higher modulus is able to withstand higher etch rates in an etch process involving ion bombardment. Therefore, AHMs with lower hydrogen content, lower RI, higher density, lower stress, and/or higher modulus have a higher selectivity and lower etching rate, and thus can be used more efficiently and effectively for HAR semiconductor processes. Accordingly, the processes herein can provide etching of HAR structures, such as those having an aspect ratio of at least about 5:1.

### Apparatus

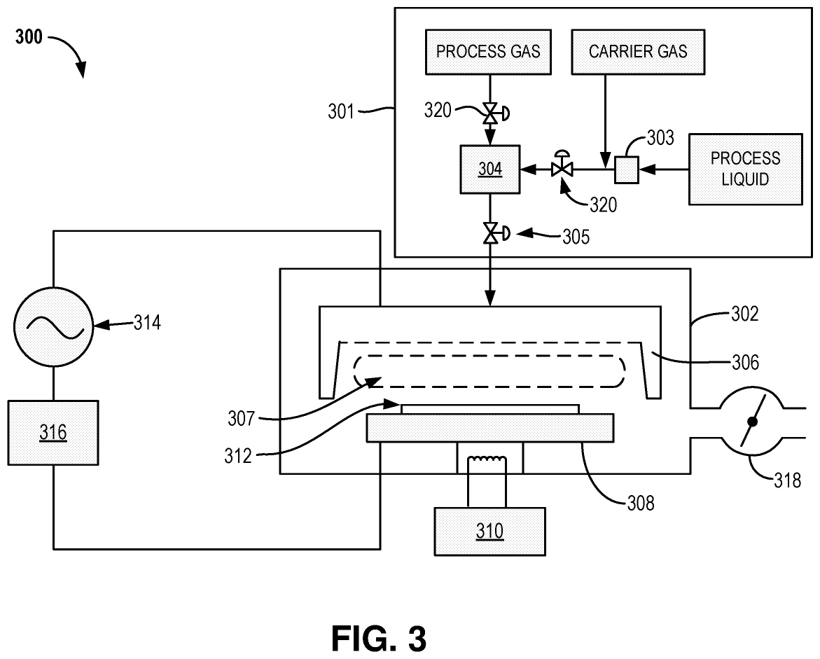

FIG. 3 schematically shows an embodiment of a process station 300 that may be used to deposit material using plasma enhanced chemical vapor deposition (PECVD). For simplicity, the process station 300 is depicted as a standalone process station having a process chamber body 302 for maintaining a low-pressure environment. However, it will be appreciated that a plurality of process stations 300 may be included in a common process tool environment. Further, it will be appreciated that, in some embodiments, one or more hardware parameters of process station 300, including those discussed in detail below, may be adjusted programmatically by one or more computer controllers.

Process station 300 fluidly communicates with reactant delivery system 301 for delivering process gases to a distribution showerhead 306. Reactant delivery system 301 includes a mixing vessel 304 for blending and/or conditioning process gases for delivery to showerhead 306. One or more mixing vessel inlet valves 320 may control introduction of process gases to mixing vessel 304. Similarly, a showerhead inlet valve 305 may control introduction of process gasses to the showerhead 306.

For example, the embodiment of FIG. 3 includes a vaporization point 303 for vaporizing liquid reactant to be supplied to mixing vessel 304. In some embodiments, vaporization point 303 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 303 may be heat traced. In some examples, mixing vessel 304 may also be heat traced. In one non-limiting example, piping downstream of vaporization point 303 has an increasing temperature profile extending from approximately 100° C. to approximately 150° C. at mixing vessel 304.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 303. In one scenario, a liquid injector may be mounted directly to mixing vessel 304. In another scenario, a liquid injector may be mounted directly to showerhead 306.

In some embodiments, a liquid flow controller upstream of vaporization point 303 may be provided for controlling a mass flow of liquid for vaporization and delivery to process station 300. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 306 distributes process gases toward substrate 312. In the embodiment shown in FIG. 3, substrate 312 is located beneath showerhead 306, and is shown resting on a pedestal 308. It will be appreciated that showerhead 306 may have any suitable shape, and may have any suitable number and arrangement of ports for distributing processes gases to substrate 312.

In some embodiments, a microvolume 307 is located beneath showerhead 306. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 308 may be raised or lowered to expose substrate 312 to microvolume 307 and/or to vary a volume of microvolume 307. For example, in a substrate transfer phase, pedestal 308 may be lowered to allow substrate 312 to be loaded onto pedestal 308. During a deposition process phase, pedestal 308 may be raised to position substrate 312 within microvolume 307. In some embodiments, microvolume 307 may completely enclose substrate 312 as well as a portion of pedestal 308 to create a region of high flow impedance during a deposition process.

Optionally, pedestal 308 may be lowered and/or raised during portions the deposition process to modulate process pressure, reactant concentration, etc., within microvolume 307. In one scenario where process chamber body 302 remains at a base pressure during the deposition process, lowering pedestal 308 may allow microvolume 307 to be evacuated. Example ratios of microvolume to process chamber volume include, but are not limited to, volume ratios between 1:500 and 1:10. It will be appreciated that, in some embodiments, pedestal height may be adjusted programmatically by a suitable computer controller.

In another scenario, adjusting a height of pedestal 308 may allow a plasma density to be varied during plasma activation and/or treatment cycles included in the deposition process. At the conclusion of the deposition process phase, pedestal 308 may be lowered during another substrate transfer phase to allow removal of substrate 312 from pedestal 308.

While the example microvolume variations described herein refer to a height-adjustable pedestal, it will be appreciated that, in some embodiments, a position of showerhead 306 may be adjusted relative to pedestal 308 to vary a volume of microvolume 307. Further, it will be appreciated that a vertical position of pedestal 308 and/or showerhead 306 may be varied by any suitable mechanism within the scope of the present disclosure. In some embodiments, pedestal 308 may include a rotational axis for rotating an orientation of substrate 312. It will be appreciated that, in some embodiments, one or more of these example adjustments may be performed programmatically by one or more suitable computer controllers.

Returning to the embodiment shown in FIG. 3, showerhead 306 and pedestal 308 electrically communicate with RF power supply 314 and matching network 316 for powering a plasma. In some embodiments, the plasma energy may be controlled by controlling one or more of a process station pressure, a gas concentration, an RF source power, an RF source frequency, and a plasma power pulse timing. For example, RF power supply 314 and matching network 316 may be operated at any suitable power to form a plasma having a desired composition of radical species. Examples of suitable powers are included above. Likewise, RF power supply 314 may provide RF power of any suitable frequency. In some embodiments, RF power supply 314 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a precursor gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 308 may be temperature controlled via heater 310. Further, in some embodiments, pressure control for deposition process station 300 may be provided by butterfly valve 318. As shown in the embodiment of FIG. 3, butterfly valve 318 throttles a vacuum provided by a downstream vacuum pump (not shown). However, in some embodiments, pressure control of process station 300 may also be adjusted by varying a flow rate of one or more gases introduced to process station 300.

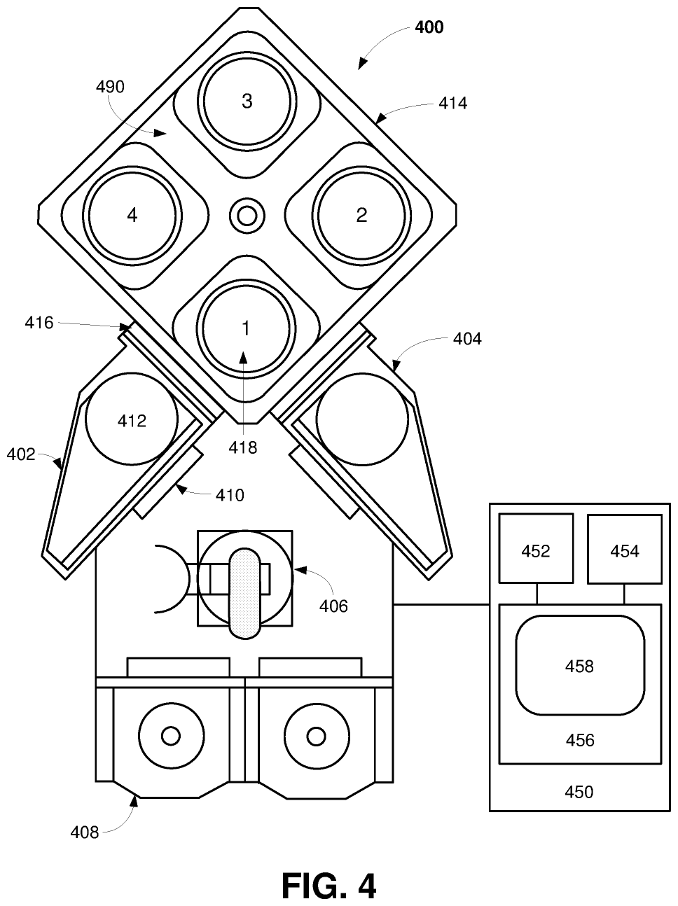

FIG. 4 shows a schematic view of an embodiment of a multi-station processing tool 400 with an inbound load lock 402 and an outbound load lock 404, either or both of which may comprise a remote plasma source. A robot 406, at atmospheric pressure, is configured to move wafers from a cassette loaded through a pod 408 into inbound load lock 402 via an atmospheric port 410. A wafer is placed by the robot 406 on a pedestal 412 in the inbound load lock 402, the atmospheric port 410 is closed, and the load lock is pumped down. Where the inbound load lock 402 comprises a remote plasma source, the wafer may be exposed to a remote plasma treatment in the load lock prior to being introduced into a processing chamber 414. Further, the wafer also may be heated in the inbound load lock 402 as well, for example, to remove moisture and adsorbed gases. Next, a chamber transport port 416 to processing chamber 414 is opened, and another robot (not shown) places the wafer into the reactor on a pedestal of a first station shown in the reactor for processing. While the embodiment depicted in FIG. 4 includes load locks, it will be appreciated that, in some embodiments, direct entry of a wafer into a process station may be provided.

The depicted processing chamber 414 comprises four process stations, numbered from 1 to 4 in the embodiment shown in FIG. 4. Each station has a heated pedestal (shown at 418 for station 1), and gas line inlets. It will be appreciated that in some embodiments, each process station may have different or multiple purposes. While the depicted processing chamber 414 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 4 also depicts an embodiment of a wafer handling system 490 for transferring wafers within processing chamber 414. In some embodiments, wafer handling system 490 may transfer wafers between various process stations and/or between a process station and a load lock. It will be appreciated that any suitable wafer handling system may be employed. Non-limiting examples include wafer carousels and wafer handling robots. FIG. 4 also depicts an embodiment of a system controller 450 employed to control process conditions and hardware states of process tool 400. System controller 450 may include one or more memory devices 456, one or more mass storage devices 454, and one or more processors 452. Processor 452 may include a CPU or computer, analog and/or digital input/output connections, stepper motor controller boards, etc.

In some embodiments, system controller 450 controls all of the activities of process tool 400. System controller 450 executes system control software 458 stored in mass storage device 454, loaded into memory device 456, and executed on processor 452. System control software 458 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 400. System control software 458 may be configured in any suitable way. For example, various process tool component subroutines or control objects may be written to control operation of the process tool components necessary to carry out various process tool processes in accordance with the disclosed methods. System control software 458 may be coded in any suitable computer readable programming language.

In some embodiments, system control software 458 may include input/output control (IOC) sequencing instructions for controlling the various parameters described above. Other computer software and/or programs stored on mass storage device 454 and/or memory device 456 associated with system controller 450 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 418 and to control the spacing between the substrate and other parts of process tool 400.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 450. The user interface may include a display screen, graphical software displays of the apparatus and/or process conditions, and user input devices such as pointing devices, keyboards, touch screens, microphones, etc.

In some embodiments, parameters adjusted by system controller 450 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 450 from various process tool sensors. The signals for controlling the process may be output on the analog and digital output connections of process tool 400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

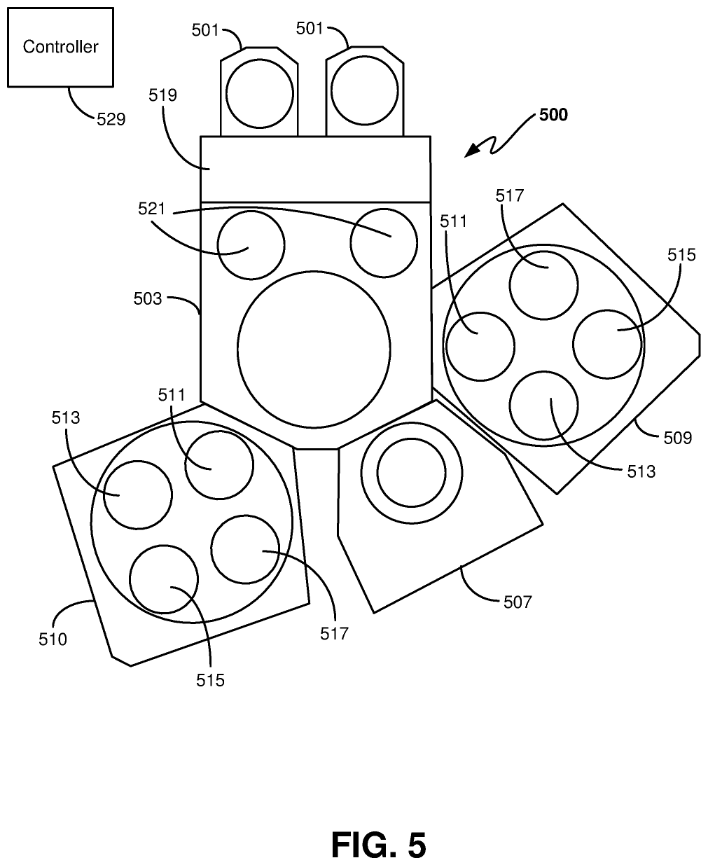

FIG. 5 is a block diagram of a processing system suitable for conducting thin film deposition processes in accordance with certain embodiments. The system 500 includes a transfer module 503. The transfer module 503 provides a clean, pressurized environment to minimize risk of contamination of substrates being processed as they are moved between various reactor modules. Mounted on the transfer module 503 are two multi-station reactors 509 and 510, each capable of performing atomic layer deposition (ALD) and/or chemical vapor deposition (CVD) according to certain embodiments. Reactors 509 and 510 may include multiple stations 511, 513, 515, and 517 that may sequentially or non-sequentially perform operations in accordance with disclosed embodiments. The stations may include a heated pedestal or substrate support, one or more gas inlets or showerhead or dispersion plate.

Also mounted on the transfer module 503 may be one or more single or multi-station modules 507 capable of performing plasma or chemical (non-plasma) pre-cleans, or any other processes described in relation to the disclosed methods. The module 507 may in some cases be used for various treatments to, for example, prepare a substrate for a deposition process. The module 507 may also be designed/configured to perform various other processes such as etching or polishing. The system 500 also includes one or more wafer source modules 501, where wafers are stored before and after processing. An atmospheric robot (not shown) in the atmospheric transfer chamber 519 may first remove wafers from the source modules 501 to loadlocks 521. A wafer transfer device (generally a robot arm unit) in the transfer module 503 moves the wafers from loadlocks 521 to and among the modules mounted on the transfer module 503.

In various embodiments, a system controller 529 is employed to control process conditions during deposition. The controller 529 will typically include one or more memory devices and one or more processors. A processor may include a CPU or computer, analog and/or digital input/output connections, stepper motor controller boards, etc.

The controller 529 may control all of the activities of the deposition apparatus. The system controller 529 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 529 may be employed in some embodiments.

Typically there will be a user interface associated with the controller 529. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 529. The signals for controlling the process are output on the analog and digital output connections of the deposition apparatus 500.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

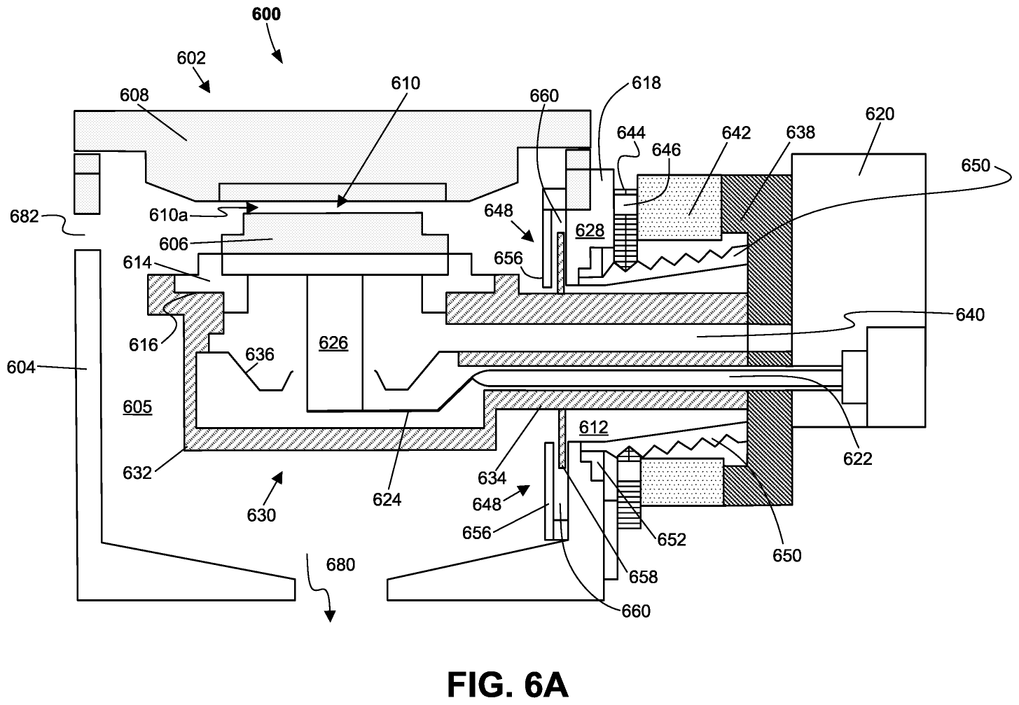

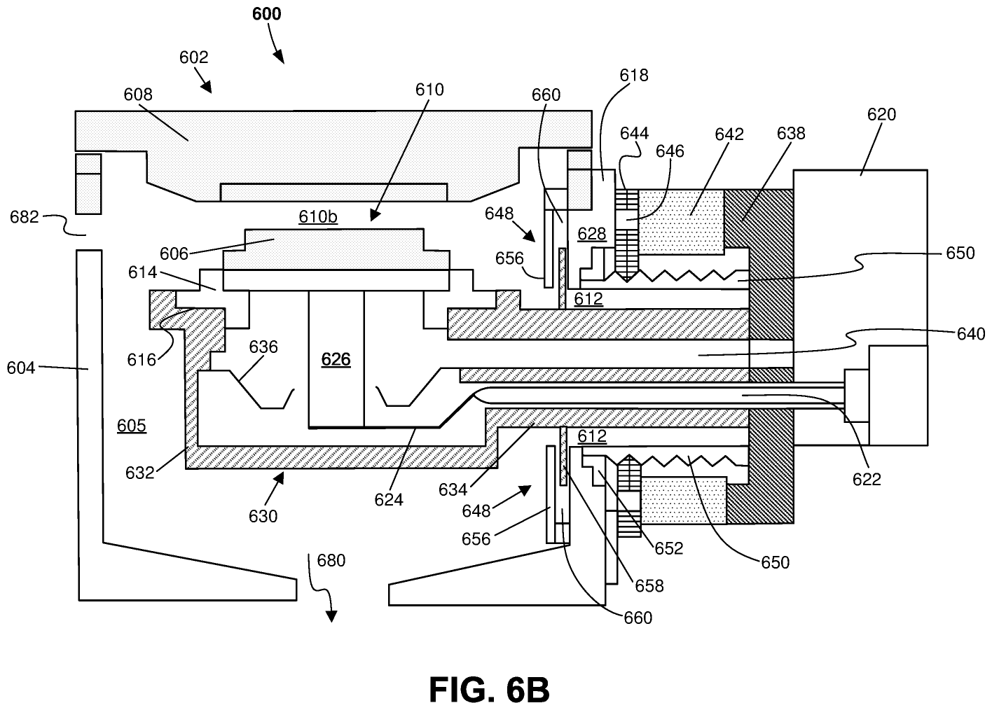

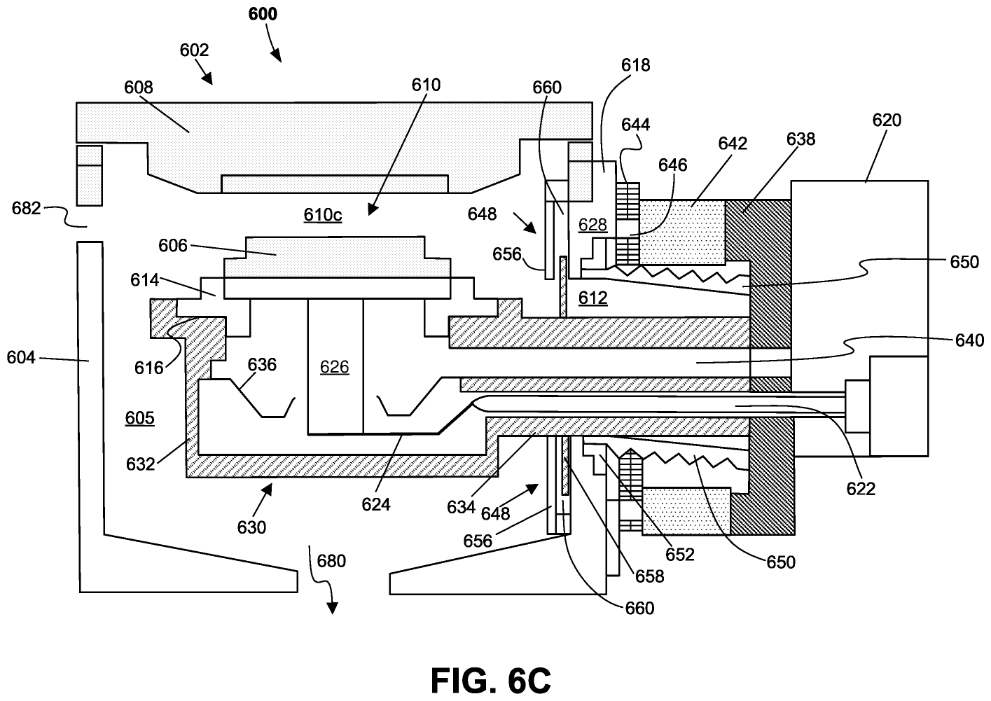

FIG. 6A-6C illustrates an embodiment of an adjustable gap capacitively coupled confined RF plasma reactor 600 that may be used for performing the etching operations described herein. As depicted, a vacuum chamber 602 includes a chamber housing 604, surrounding an interior space housing a lower electrode 606. In an upper portion of the chamber 602, an upper electrode 608 is vertically spaced apart from the lower electrode 606. Planar surfaces of the upper and lower electrodes 608, 606 are substantially parallel and orthogonal to the vertical direction between the electrodes. Preferably, the upper and lower electrodes 608, 606 are circular and coaxial with respect to a vertical axis. A lower surface of the upper electrode 608 faces an upper surface of the lower electrode 606. The spaced apart facing electrode surfaces define an adjustable gap 610 therebetween. During operation, the lower electrode 606 is supplied RF power by an RF power supply (match) 620. RF power is supplied to the lower electrode 606 though an RF supply conduit 622, an RF strap 624, and an RF power member 626. A grounding shield 636 may surround the RF power member 626 to provide a more uniform RF field to the lower electrode 606. As described in U.S. Pat. No. 7,732,728, the entire contents of which are herein incorporated by reference, a wafer is inserted through wafer port 682 and supported in the gap 610 on the lower electrode 606 for processing, a process gas is supplied to the gap 610 and excited into plasma state by the RF power. The upper electrode 608 can be powered or grounded.

In the embodiment shown in FIG. 6A-6C, the lower electrode 606 is supported on a lower electrode support plate 616. An insulator ring 614 interposed between the lower electrode 606 and the lower electrode support plate 616 insulates the lower electrode 606 from the support plate 616.

An RF bias housing 630 supports the lower electrode 606 on an RF bias housing bowl 632. The bowl 632 is connected through an opening in a chamber wall plate 618 to a conduit support plate 638 by an arm 634 of the RF bias housing 630. In a preferred embodiment, the RF bias housing bowl 632 and RF bias housing arm 634 are integrally formed as one component, however, the arm 634 and bowl 632 can also be two separate components bolted or joined together.

The RF bias housing arm 634 includes one or more hollow passages for passing RF power and facilities, such as gas coolant, liquid coolant, RF energy, cables for lift pin control, electrical monitoring and actuating signals from outside the vacuum chamber 602 to inside the vacuum chamber 602 at a space on the backside of the lower electrode 606. The RF supply conduit 622 is insulated from the RF bias housing arm 634, the RF bias housing arm 634 providing a return path for RF power to the RF power supply 620. A facilities conduit 640 provides a passageway for facility components. Further details of the facility components are described in U.S. Pat. Nos. 5,948,704 and 7,732,728 and are not shown here for simplicity of description. The gap 610 is preferably surrounded by a confinement ring assembly or shroud (not shown), details of which can be found in U.S. Pat. No. 7,740,736 herein incorporated by reference. The interior of the vacuum chamber 602 is maintained at a low pressure by connection to a vacuum pump through vacuum portal 680.

The conduit support plate 638 is attached to an actuation mechanism 642. Details of an actuation mechanism are described in U.S. Pat. No. 7,732,728, incorporated herein by above. The actuation mechanism 642, such as a servo mechanical motor, stepper motor or the like is attached to a vertical linear bearing 644, for example, by a screw gear 646 such as a ball screw and motor for rotating the ball screw. During operation to adjust the size of the gap 610, the actuation mechanism 642 travels along the vertical linear bearing 644. FIG. 6A illustrates the arrangement when the actuation mechanism 642 is at a high position on the linear bearing 644 resulting in a small gap 610a. FIG. 6B illustrates the arrangement when the actuation mechanism 642 is at a mid-position on the linear bearing 644. As shown, the lower electrode 606, the RF bias housing 630, the conduit support plate 638, the RF power supply 620 have all moved lower with respect to the chamber housing 604 and the upper electrode 608, resulting in a medium size gap 610b.

FIG. 6C illustrates a large gap 610c when the actuation mechanism 642 is at a low position on the linear bearing. Preferably, the upper and lower electrodes 608, 606 remain co-axial during the gap adjustment and the facing surfaces of the upper and lower electrodes across the gap remain parallel.

This embodiment allows the gap 610 between the lower and upper electrodes 606, 608 in the CCP chamber 602 during multi-step process recipes (BARC, HARC, and STRIP, etc.) to be adjusted, for example, in order to maintain uniform etch across a large diameter substrate such as 300 mm wafers or flat panel displays. In particular, this chamber pertains to a mechanical arrangement that permits the linear motion necessary to provide the adjustable gap between lower and upper electrodes 606, 608.

FIG. 6A illustrates laterally deflected bellows 650 sealed at a proximate end to the conduit support plate 638 and at a distal end to a stepped flange 628 of chamber wall plate 618. The inner diameter of the stepped flange defines an opening 612 in the chamber wall plate 618 through which the RF bias housing arm 634 passes. The distal end of the bellows 650 is clamped by a clamp ring 652.

The laterally deflected bellows 650 provides a vacuum seal while allowing vertical movement of the RF bias housing 630, conduit support plate 638 and actuation mechanism 642. The RF bias housing 630, conduit support plate 638 and actuation mechanism 642 can be referred to as a cantilever assembly. Preferably, the RF power supply 620 moves with the cantilever assembly and can be attached to the conduit support plate 638. FIG. 6B shows the bellows 650 in a neutral position when the cantilever assembly is at a mid-position. FIG. 6C shows the bellows 650 laterally deflected when the cantilever assembly is at a low position.

A labyrinth seal 648 provides a particle barrier between the bellows 650 and the interior of the plasma processing chamber housing 604. A fixed shield 656 is immovably attached to the inside inner wall of the chamber housing 604 at the chamber wall plate 618 so as to provide a labyrinth groove 660 (slot) in which a movable shield plate 658 moves vertically to accommodate vertical movement of the cantilever assembly. The outer portion of the movable shield plate 658 remains in the slot at all vertical positions of the lower electrode 606.

In the embodiment shown, the labyrinth seal 648 includes a fixed shield 656 attached to an inner surface of the chamber wall plate 618 at a periphery of the opening 612 in the chamber wall plate 618 defining a labyrinth groove 660. The movable shield plate 658 is attached and extends radially from the RF bias housing arm 634 where the arm 634 passes through the opening 612 in the chamber wall plate 618. The movable shield plate 658 extends into the labyrinth groove 660 while spaced apart from the fixed shield 656 by a first gap and spaced apart from the interior surface of the chamber wall plate 618 by a second gap allowing the cantilevered assembly to move vertically. The labyrinth seal 648 blocks migration of particles spalled from the bellows 650 from entering the vacuum chamber interior 605 and blocks radicals from process gas plasma from migrating to the bellows 650 where the radicals can form deposits which are subsequently spalled.

FIG. 6A shows the movable shield plate 658 at a higher position in the labyrinth groove 660 above the RF bias housing arm 634 when the cantilevered assembly is in a high position (small gap 610a). FIG. 6C shows the movable shield plate 658 at a lower position in the labyrinth groove 660 above the RF bias housing arm 634 when the cantilevered assembly is in a low position (large gap 610c). FIG. 6B shows the movable shield plate 658 in a neutral or mid position within the labyrinth groove 660 when the cantilevered assembly is in a mid-position (medium gap 610b). While the labyrinth seal 648 is shown as symmetrical about the RF bias housing arm 634, in other embodiments the labyrinth seal 648 may be asymmetrical about the RF bias arm 634.

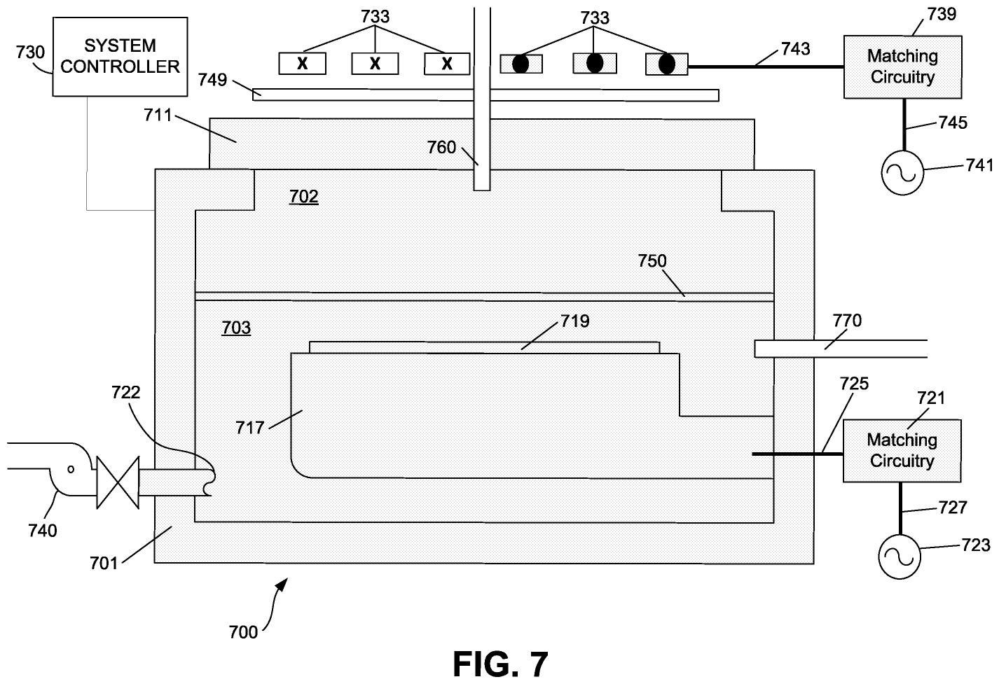

FIG. 7 schematically shows a cross-sectional view of an inductively coupled plasma etching apparatus 700 in accordance with certain embodiments herein. A Kiyo™ reactor, produced by Lam Research Corp. of Fremont, CA, is an example of a suitable reactor that may be used to implement the techniques described herein. The inductively coupled plasma etching apparatus 700 includes an overall etching chamber structurally defined by chamber walls 701 and a window 711. The chamber walls 701 may be fabricated from stainless steel or aluminum. The window 711 may be fabricated from quartz or other dielectric material. An optional internal plasma grid 750 divides the overall etching chamber into an upper sub-chamber 702 and a lower sub-chamber 703. The plasma grid 750 may include a single grid or multiple individual grids. In many embodiments, plasma grid 750 may be removed, thereby utilizing a chamber space made of sub-chambers 702 and 703.

A chuck 717 is positioned within the lower sub-chamber 703 near the bottom inner surface. The chuck 717 is configured to receive and hold a semiconductor wafer 719 upon which the etching process is performed. The chuck 717 can be an electrostatic chuck for supporting the wafer 719 when present. In some embodiments, an edge ring (not shown) surrounds chuck 717, and has an upper surface that is approximately planar with a top surface of a wafer 719, when present over chuck 717. The chuck 717 also includes electrostatic electrodes for chucking and dechucking the wafer. A filter and DC clamp power supply (not shown) may be provided for this purpose. Other control systems for lifting the wafer 719 off the chuck 717 can also be provided. The chuck 717 can be electrically charged using an RF power supply 723. The RF power supply 723 is connected to matching circuitry 721 through a connection 727. The matching circuitry 721 is connected to the chuck 717 through a connection 725. In this manner, the RF power supply 723 is connected to the chuck 717.

A coil 733 is positioned above window 711. The coil 733 is fabricated from an electrically conductive material and includes at least one complete turn. The exemplary coil 733 shown in FIG. 7 includes three turns. The cross-sections of coil 733 are shown with symbols, and coils having an “X” extend rotationally into the page, while coils having a “.” extend rotationally out of the page. An RF power supply 741 is configured to supply RF power to the coil 733. In general, the RF power supply 741 is connected to matching circuitry 739 through a connection 745. The matching circuitry 739 is connected to the coil 733 through a connection 743. In this manner, the RF power supply 741 is connected to the coil 733. An optional Faraday shield 749 is positioned between the coil 733 and the window 711. The Faraday shield 749 is maintained in a spaced apart relationship relative to the coil 733. The Faraday shield 749 is disposed immediately above the window 711. The coil 733, the Faraday shield 749, and the window 711 are each configured to be substantially parallel to one another. The Faraday shield may prevent metal or other species from depositing on the dielectric window of the plasma chamber.

Process gases may be supplied through a main injection port 760 positioned in the upper chamber and/or through a side injection port 770, sometimes referred to as an STG. A vacuum pump, e.g., a one or two stage mechanical dry pump and/or turbomolecular pump 740, may be used to draw process gases out of the process chamber and to maintain a pressure within the process chamber 700 by using a closed-loop-controlled flow restriction device, such as a throttle valve (not shown) or a pendulum valve (not shown), during operational plasma processing.

During operation of the apparatus, one or more reactant gases may be supplied through injection ports 760 and/or 770. In certain embodiments, gas may be supplied only through the main injection port 760, or only through the side injection port 770. In some cases, the injection ports may be replaced by showerheads. The Faraday shield 749 and/or optional grid 750 may include internal channels and holes that allow delivery of process gases to the chamber. Either or both of Faraday shield 749 and optional grid 750 may serve as a showerhead for delivery of process gases.

Radio frequency power is supplied from the RF power supply 741 to the coil 733 to cause an RF current to flow through the coil 733. The RF current flowing through the coil 733 generates an electromagnetic field about the coil 733. The electromagnetic field generates an inductive current within the upper sub-chamber 702. The physical and chemical interactions of various generated ions and radicals with the wafer 719 selectively etch features of the wafer.

If the plasma grid 750 is used such that there is both an upper sub-chamber 702 and a lower sub-chamber 703, the inductive current acts on the gas present in the upper sub-chamber 702 to generate an electron-ion plasma in the upper sub-chamber 702. The optional internal plasma grid 750, if present, may act to limit the number of hot electrons in the lower sub-chamber 703. In some embodiments, the apparatus is designed and operated such that the plasma present in the lower sub-chamber 703 is an ion-ion plasma. In other embodiments, the apparatus may be designed and operated such that the plasma present in the lower sub-chamber 703 is an electron-ion plasma. Internal plasma grids and ion-ion plasma are further discussed in U.S. patent application Ser. No. 14/082,009, filed Nov. 15, 2013, and titled “INTERNAL PLASMA GRID FOR SEMICONDUCTOR FABRICATION,” and in U.S. Pat. No. 9,245,761, each of which is herein incorporated by reference in its entirety.

Volatile etching byproducts may be removed from the lower-sub chamber 703 through port 722. The chuck 717 disclosed herein may operate at elevated temperatures ranging between about 30° C. and about 250° C. In some cases, the chuck 717 may also operate at lower temperatures, for example when the chuck 717 is actively chilled. In such cases the chuck 717 may operate at substantially lower temperatures, as desired. The temperature will depend on the etching process operation and specific recipe. In some embodiments, the chamber 701 may operate at pressures in the range of between about 1 mTorr and about 95 mTorr. In certain embodiments, the pressure may be higher.

Chamber 701 may be coupled to facilities (not shown) when installed in a clean room or a fabrication facility. Facilities include plumbing that provide processing gases, vacuum, temperature control, and environmental particle control. These facilities are coupled to chamber 701, when installed in the target fabrication facility. Additionally, chamber 701 may be coupled to a transfer chamber that allows robotics to transfer semiconductor wafers into and out of chamber 701 using typical automation.

In some embodiments, a system controller 730 (which may include one or more physical or logical controllers) controls some or all of the operations of an etching chamber. The system controller 730 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the system controller 730 or they may be provided over a network. In certain embodiments, the system controller 730 executes system control software.

In some cases, the system controller 730 controls gas concentration, wafer movement, and/or the power supplied to the coils 733 and/or electrostatic chuck 717. The system controller 730 may control the gas concentration by, for example, opening and closing relevant valves to produce one or more inlet gas stream that provide the necessary reactant(s) at the proper concentration(s). The wafer movement may be controlled by, for example, directing a wafer positioning system to move as desired. The power supplied to the coils 733 and/or chuck 717 may be controlled to provide particular RF power levels. Similarly, if the internal grid 750 is used, any RF power applied to the grid may be adjusted by the system controller 730.

The system controller 730 may control these and other aspects based on sensor output (e.g., when power, potential, pressure, etc. reach a certain threshold), the timing of an operation (e.g., opening valves at certain times in a process), or based on received instructions from the user. An example controller is further discussed below.

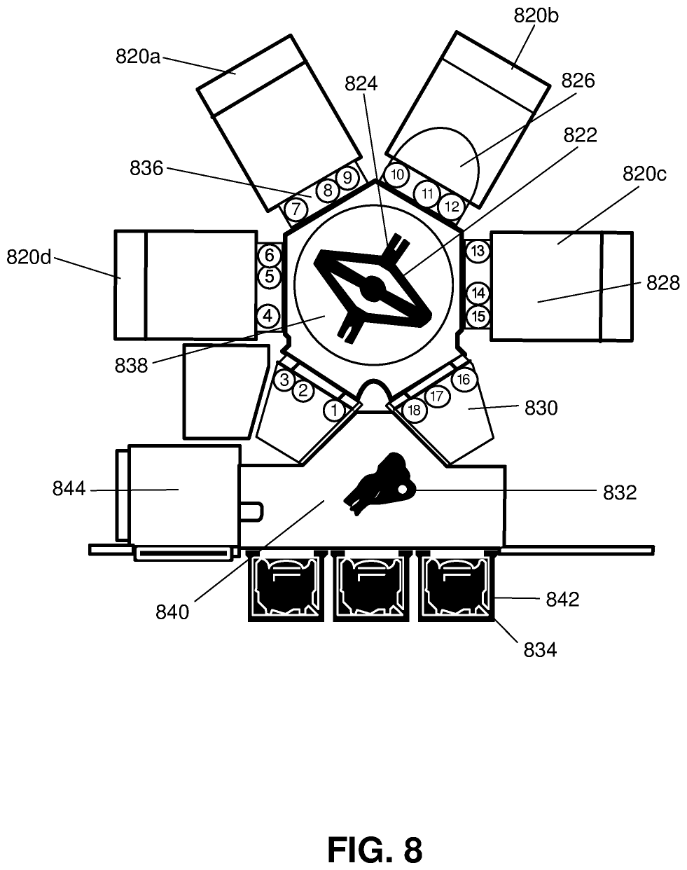

FIG. 8 depicts a semiconductor process cluster architecture with various modules that interface with a vacuum transfer module 838 (VTM). The arrangement of transfer modules to “transfer” substrates among multiple storage facilities and processing modules may be referred to as a “cluster tool architecture” system. Airlock 830, also known as a loadlock or transfer module, is shown in VTM 838 with four processing modules 820a-820d, which may be individually optimized to perform various fabrication processes. By way of example, processing modules 820a-820d may be implemented to perform substrate etching, deposition, ion implantation, substrate cleaning, sputtering, and/or other semiconductor processes as well as laser metrology and other defect detection and defect identification methods. One or more of the processing modules (any of 820a-820d) may be implemented as disclosed herein, i.e., for etching recessed features into substrates. Airlock 830 and process modules 820a-820d may be referred to as “stations.” Each station has a facet 836 that interfaces the station to VTM 838. Inside the facets, sensors 1-18 are used to detect the passing of substrate 826 when moved between respective stations.

Robot 822 transfers substrates between stations. In one implementation, the robot may have one arm, and in another implementation, the robot may have two arms, where each arm has an end effector 824 to pick substrates for transport. Front-end robot 832, in atmospheric transfer module (ATM) 840, may be used to transfer substrates from cassette or Front Opening Unified Pod (FOUP) 834 in Load Port Module (LPM) 842 to airlock 830. Module center 828 inside process modules 820a-820d may be one location for placing the substrate. Aligner 844 in ATM 840 may be used to align substrates.

In an exemplary processing method, a substrate is placed in one of the FOUPs 834 in the LPM 842. Front-end robot 832 transfers the substrate from the FOUP 834 to the aligner 844, which allows the substrate 826 to be properly centered before it is etched, or deposited upon, or otherwise processed. After being aligned, the substrate is moved by the front-end robot 832 into an airlock 830. Because airlock modules have the ability to match the environment between an ATM and a VTM, the substrate is able to move between the two pressure environments without being damaged. From the airlock module 830, the substrate is moved by robot 822 through VTM 838 and into one of the process modules 820a-820d, for example process module 820a. In order to achieve this substrate movement, the robot 822 uses end effectors 824 on each of its arms. Once the wafer 826 has been processed, it is moved by robot 822 from the process modules 820a-820d to an airlock module 830. From here, the wafer 826 may be moved by the front-end robot 832 to one of the FOUPs 834 or to the aligner 844.

It should be noted that the computer controlling the substrate movement can be local to the cluster architecture or can be located external to the cluster architecture in the manufacturing floor, or in a remote location and connected to the cluster architecture via a network.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Definitions

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. Such an aliphatic can be unsubstituted or substituted with one or more groups, such as groups described herein for an alkyl group. Yet other substitution groups can include aromatic, haloaromatic, halo, nitrate, cyano, sulfonate, sulfonyl, or others.

By “alkane” is meant a compound having one or more alkyl groups, as defined herein. An alkane can be unsubstituted or substituted with one or more substituents described herein, e.g., such as for alkyl.

By “alkene” is meant a compound having one or more alkenyl groups, as defined herein. An alkene can be unsubstituted or substituted with one or more substituents described herein, e.g., such as for alkyl.

By “alkyne” is meant a compound having one or more alkynyl groups, as defined herein. An alkyne can be unsubstituted or substituted with one or more substituents described herein, e.g., such as for alkyl.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17)N-protected amino; (18) nitro (e.g., —NO₂); (19) oxo (e.g., ═O); (20) C₁₋₆ thioalkoxy (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₈ aryl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. Such an aromatic can be unsubstituted or substituted with one or more groups, such as groups described herein for an alkyl or aryl group. Yet other substitution groups can include aliphatic, haloaliphatic, halo, nitrate, cyano, sulfonate, sulfonyl, or others.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amine (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L2 is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein; and each of R³ and R⁴ is, independently, H or C₁₋₆ alkyl); (12) heteroaryl; (13) C₁₋₆ alkyl-C₄₋₁₈ aryl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₁₋₆ alkyl-C₃₋₈ cycloalkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31)N-protected amino; (32)N-protected amino-C₁₋₆ alkyl; (33) oxo (e.g., ═O); (34) C₁₋₆ thioalkoxy (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “carbocycle” is meant a compound having one or more cycloaliphatic or multicycloaliphatic moieties, as defined herein. A carbocycle can be unsubstituted or substituted with one or more substituents described herein, e.g., such as for alkyl.

By “cyano” is meant a —CN group.

By “cyanoalkane” is meant an alkane, as defined herein, in which one or more hydrogen atoms is replaced with cyano.

By “cyanoaromatic” is meant an aromatic, as defined herein, in which one or more hydrogen atoms is replaced with cyano.

By “cycloaliphatic” is meant an aliphatic group, as defined herein, that is cyclic. Such cycloaliphatic groups can be saturated or unsaturated.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl.

By “halo” is meant F, Cl, Br, or I. When used as a prefix, “halo” indicates that the group can include one or more halo substitutions.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkane” is meant an alkane, as defined herein, in which one or more hydrogen atoms, such as one to 10 hydrogen atoms, independently is replaced with a halogen atom, such as fluoro, bromo, chloro, or iodo.

By “haloalkene” is meant an alkene, as defined herein, in which one or more hydrogen atoms, such as one to 10 hydrogen atoms, independently is replaced with a halogen atom, such as fluoro, bromo, chloro, or iodo.

By “haloalkenyl” is meant an alkenyl group, as defined herein, where one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloalkyne” is meant an alkyne, as defined herein, in which one or more hydrogen atoms, such as one to 10 hydrogen atoms, independently is replaced with a halogen atom, such as fluoro, bromo, chloro, or iodo.

By “haloalkynyl” is meant an alkynyl group, as defined herein, where one or more hydrogen atoms, such as one to 10 hydrogen atoms, independently is replaced with a halogen atom, such as fluoro, bromo, chloro, or iodo.

By “haloaromatic” is meant an aromatic, as defined herein, in which one or more hydrogen atoms, such as one to 10 hydrogen atoms, independently is replaced with a halogen atom, such as fluoro, bromo, chloro, or iodo. Such hydrogen atom(s) to be replaced with a halogen can be present within a ring or within a substitution disposed on the ring.

By “haloaryl” is meant an aryl group, as defined herein, where one or more hydrogen atoms, such as one to 10 hydrogen atoms, independently is replaced with a halogen atom, such as fluoro, bromo, chloro, or iodo. In an independent embodiment, haloaryl can be a -Ph-CX₃ group, wherein Ph is phenyl and each X independently can be selected from fluoro, bromo, chloro, or iodo. In some embodiments, the haloaryl group is -L-X, in which L is an aryl group, as defined herein, and X is fluoro, bromo, chloro, or iodo. In other embodiments, the haloaryl group is -L-C(X)(R¹)—R², in which L is an aryl group, as defined herein; X is fluoro, bromo, chloro, or iodo; and each of R¹ and R² is, independently, H or alkyl, as defined herein.

By “halocarbocycle” is meant a carbocycle, as defined herein, in which one or more hydrogen atoms, such as one to 10 hydrogen atoms, independently is replaced with a halogen atom, such as fluoro, bromo, chloro, or iodo.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “halosulfonyl” is meant an —S(O)₂X group or a —OS(O)X group, in which X is halo (e.g., fluoro, bromo, chloro, or iodo).

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heterocycle” is meant a compound having one or more heterocyclyl moieties. Non-limiting heterocycles include optionally substituted imidazole, optionally substituted triazole, optionally substituted tetrazole, optionally substituted pyrazole, optionally substituted imidazoline, optionally substituted pyrazoline, optionally substituted imidazolidine, optionally substituted pyrazolidine, optionally substituted pyrrole, optionally substituted pyrroline, optionally substituted pyrrolidine, optionally substituted tetrahydrofuran, optionally substituted furan, optionally substituted thiophene, optionally substituted oxazole, optionally substituted isoxazole, optionally substituted isothiazole, optionally substituted thiazole, optionally substituted oxathiolane, optionally substituted oxadiazole, optionally substituted thiadiazole, optionally substituted sulfolane, optionally substituted succinimide, optionally substituted thiazolidinedione, optionally substituted oxazolidone, optionally substituted hydantoin, optionally substituted pyridine, optionally substituted piperidine, optionally substituted pyridazine, optionally substituted piperazine, optionally substituted pyrimidine, optionally substituted pyrazine, optionally substituted triazine, optionally substituted pyran, optionally substituted pyrylium, optionally substituted tetrahydropyran, optionally substituted dioxine, optionally substituted dioxane, optionally substituted dithiane, optionally substituted trithiane, optionally substituted thiopyran, optionally substituted thiane, optionally substituted oxazine, optionally substituted morpholine, optionally substituted thiazine, optionally substituted thiomorpholine, optionally substituted cytosine, optionally substituted thymine, optionally substituted uracil, optionally substituted thiomorpholine dioxide, optionally substituted indene, optionally substituted indoline, optionally substituted indole, optionally substituted isoindole, optionally substituted indolizine, optionally substituted indazole, optionally substituted benzimidazole, optionally substituted azaindole, optionally substituted azaindazole, optionally substituted pyrazolopyrimidine, optionally substituted purine, optionally substituted benzofuran, optionally substituted isobenzofuran, optionally substituted benzothiophene, optionally substituted benzisoxazole, optionally substituted anthranil, optionally substituted benzisothiazole, optionally substituted benzoxazole, optionally substituted benzthiazole, optionally substituted benzthiadiazole, optionally substituted adenine, optionally substituted guanine, optionally substituted tetrahydroquinoline, optionally substituted dihydroquinoline, optionally substituted dihydroisoquinoline, optionally substituted quinoline, optionally substituted isoquinoline, optionally substituted quinolizine, optionally substituted quinoxaline, optionally substituted phthalazine, optionally substituted quinazoline, optionally substituted cinnoline, optionally substituted naphthyridine, optionally substituted pyridopyrimidine, optionally substituted pyridopyrazine, optionally substituted pteridine, optionally substituted chromene, optionally substituted isochromene, optionally substituted chromenone, optionally substituted benzoxazine, optionally substituted quinolinone, optionally substituted isoquinolinone, optionally substituted carbazole, optionally substituted dibenzofuran, optionally substituted acridine, optionally substituted phenazine, optionally substituted phenoxazine, optionally substituted phenothiazine, optionally substituted phenoxathiine, optionally substituted quinuclidine, optionally substituted azaadamantane, optionally substituted dihydroazepine, optionally substituted azepine, optionally substituted diazepine, optionally substituted oxepane, optionally substituted thiepine, optionally substituted thiazepine, optionally substituted azocane, optionally substituted azocine, optionally substituted thiocane, optionally substituted azonane, optionally substituted azecine, etc. Optional substitutions include any described herein for aryl. Heterocycles can also include cations and/or salts of any of these.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl, benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “multicycloaliphatic” is meant an aliphatic group, as defined herein, that has more than one cyclic group.

By “nitrate” is meant a —ONO₂ group.

By “sulfonyl” is meant an —S(O)₂— group or a —OS(O)— group.

By “sulfonate” is meant an —OS(O)₂— group. Non-limiting sulfonate groups include —OSO₂R, where R is selected from hydrogen, halo, aliphatic, alkyl, heteroaliphatic, heteroalkyl, alkoxy, haloaliphatic, haloalkyl, haloheteroaliphatic, aromatic, aryl, haloaryl, as defined herein, or any combination thereof. Other non-limiting sulfonate groups include triflate (—OTf or —OS(O)₂CF₃), mesylate (—OMs or —O(SO)₂CH₃), tosylate (—OTs or —O(SO)₂(p-tolyl)), brosylate (—OBs or —O(SO)₂(p-bromophenyl)), nosylate (—ONs or —O(SO)₂(p-nitrophenyl)), or tresylate (—OS(O)₂CH₂CF₃).

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
exposing a surface of a semiconductor substrate in a processing chamber to a halogen-containing precursor, wherein the halogen-containing precursor is delivered to the processing chamber or formed in situ within the processing chamber; and
depositing on the surface an ashable hard mask film (AHM) by a plasma enhanced chemical vapor deposition (PECVD) process.

2. The method of claim 1, wherein said exposing comprises delivering the halogen-containing precursor to the processing chamber.

3. The method of claim 2, wherein the halogen-containing precursor comprises a straight-chain or branched-chain aliphatic moiety, an aromatic moiety, a cycloaliphatic moiety, or a multicycloaliphatic moiety, in which each moiety comprises one or more halo substitutions.

4. The method of claim 3, wherein the one or more halo substitutions is provided on an sp carbon, sp² carbon, an sp³ carbon, a branched portion, or an unbranched portion.

5. The method of claim 3, wherein the halogen-containing precursor comprises a halocarbon, a haloaliphatic, a haloalkane, a haloalkene, a haloalkyne, a haloaromatic, or a halocarbocycle.

6. The method of claim 1, wherein said exposing further comprises delivering a process gas comprising the halogen-containing precursor and an inert gas.

7. The method of claim 1, wherein said exposing comprises forming the halogen-containing precursor in situ within the processing chamber with an organic reactant and a halogen-containing reactant.

8. The method of claim 7, wherein the organic reactant comprises a pure hydrocarbon reactant, a halocarbon reactant, a hydrocarbon reactant having a leaving group, or a heterocycle reactant.

9. The method of claim 8, wherein the pure hydrocarbon reactant comprises an alkane, an alkene, an alkyne, an aromatic, or a carbocycle.

10. The method of claim 8, wherein the halocarbon reactant comprises an alkane, an alkene, an alkyne, an aromatic, or a carbocycle comprising one or more halo substitutions.

11. The method of claim 8, wherein the hydrocarbon reactant having the leaving group comprises an alkane, an alkene, an alkyne, an aromatic, or a carbocycle comprising one or more leaving groups.

12. The method of claim 11, wherein the hydrocarbon reactant having the leaving group comprises a halosulfonyl group, a sulfonate group, a cyano group, a nitrous oxide group (N₂O), or a nitrate group (—ONO₂).

13. The method of claim 11, wherein the hydrocarbon reactant having the leaving group comprises an alkyl sulfonyl halide, an aryl sulfonyl halide, an alkyl triflate, an aryl triflate, an alkyl mesylate, an aryl mesylate, a cyanoalkane, a cyanoaromatic, an alkyl nitrate, or an aryl nitrate.

14. The method of claim 7, wherein the halogen-containing reactant comprises a halide, a halogen gas, a tetrahalosilane, a trihalosilane, a dihalosilane, a monohalosilane, or a Grignard reagent.

15. The method of claim 7, wherein said exposing further comprises delivering a first process gas comprising the organic reactant with a first inert gas and a second process gas comprising the halogen-containing reactant with a second inert gas.

16. The method of claim 1, wherein the halogen-containing precursor comprises a ratio of carbon atoms to halogen atoms (a C:H ratio) of at least about 1:3 and/or a ratio of halogen atoms to hydrogen atoms (an X:H ratio) of at least about 1:20.

17. The method of claim 1, wherein said exposing further comprises delivering a hydrogen (H₂) gas.

18. The method of claim 1, wherein said exposing further comprises delivering a hydrocarbon precursor with the halogen-containing precursor.

19. The method of claim 18, wherein the hydrocarbon precursor comprises an alkane, an alkene, an alkyne, an aromatic, or a carbocycle.

20. The method of claim 1, wherein said exposing further comprises delivering a metal-containing reactant and said depositing provides a metal-doped AHM.

21. The method of claim 20, wherein the metal-containing reactant comprises an organometallic reagent, a metal halide, or a metal hydride.

22. The method of claim 1, wherein said PECVD process comprises igniting a plasma comprising a low frequency (LF) component and/or a high frequency (HF) component.

23. The method of claim 1, wherein the method provides a multilayer stack comprising the AHM.

24. The method of claim 1, further comprising:
patterning the AHM, thereby providing a patterned AHM; and
etching the patterned AHM to define features of the AHM in the semiconductor substrate.

25. The method of claim 24, further comprising:
etching one or more layers in the semiconductor substrate underlying the patterned AHM; and
removing the patterned AHM.

26. An apparatus for forming an ashable hard mask (AHM), the apparatus comprising:
a processing chamber;
a substrate holder in the processing chamber;
one or more gas inlets for flowing gases into the processing chamber;
a plasma generator for generating plasmas within the processing chamber; and
one or more controllers comprising machine-readable instructions for operating the substrate holder, the one or more gas inlets, and the plasma generator to deposit the AHM onto a semiconductor substrate, the instructions of the one or more controllers comprising instructions for:
(a) causing operation of the one or more gas inlets to flow a halogen-containing precursor or an organic reactant with a halogen-containing reactant into the processing chamber, wherein the organic reactant and the halogen-containing reactant form the halogen-containing precursor, thereby exposing a surface of the semiconductor substrate held in the substrate holder to the halogen-containing precursor; and
(b) causing operation of the plasma generator to generate a plasma to form the AHM on the surface.

27. The apparatus of claim 26, wherein the instructions of the one or more controllers further comprise instructions for:
(c) prior to causing operation of the plasma generator, further causing operation of the one or more gas inlets to flow a hydrogen (H₂) gas into the processing chamber.

28. The apparatus of claim 26, wherein the instructions of the one or more controllers further comprise instructions for:
(c) prior to causing operation of the plasma generator, further causing operation of the one or more gas inlets to flow a metal-containing reactant into the processing chamber.

29. The apparatus of claim 26, wherein the instructions of the one or more controllers further comprise instructions for:
(c) causing operation of the substrate holder at a temperature of at least about 50° C.

30. The apparatus of claim 26, wherein the plasma generator is operated to provide a plasma comprising a low frequency (LF) component and/or a high frequency (HF) component.
